(19) United States
(12) Patent Application Publication
(10) Pub. No.: US 2023/0397172 A1
(43) Pub. Date: Dec. 7, 2023

(54) SIGNALING OF GRADIENT VECTORS FOR FEDERATED LEARNING IN A WIRELESS COMMUNICATIONS SYSTEM

(71) Applicant: QUALCOMM Incorporated, San Diego, CA (US)

(72) Inventors: Qiaoyu LI, Beijing (CN); Hao XU, Beijing (CN); Yu ZHANG, San Diego, CA (US); Chenxi HAO, Beijing (CN); Chao WEI, Beijing (CN); Rui HU, Beijing (CN); Liangming WU, Beijing (CN); Ruiming ZHENG, Beijing (CN); Yin HUANG, Beijing (CN); Yuwei REN, Beijing (CN)

(21) Appl. No.: 18/249,191

(22) PCT Filed: Dec. 29, 2020
(86) PCT No.: PCT/CN2020/140705

§ 371 Date: Apr. 14, 2023

(51) Int. Cl. H04W 72/044; G06N 20/00; H04W 28/02; H04L 41/16

(52) U.S. Cl. CPC H04W 72/044; G06N 20/00; H04W 28/0252; H04L 41/16

(57) ABSTRACT

Methods, systems, and devices for wireless communications are described that support signaling of compressed gradient vectors in a machine learning system that utilizes federated learning. The compressed gradient vectors may be used to report stochastic gradients from multiple edge devices (e.g., multiple user equipment (UE) devices) that are combined into a global model at an edge server (e.g., a base station). A base station may configure a UE with one or more parameters for quantizing a local stochastic gradient, and for reporting the quantized local stochastic gradient in a set of compressed gradient vectors. Each vector of the compressed gradient vectors may be associated with a different stage of a multi-stage compression procedure for reporting the local stochastic gradient, and multiple reports from multiple UEs may be aggregated in a federated learning procedure associated with a machine learning algorithm.

### CROSS REFERENCE

The present Application is a 371 national stage filing of International PCT Application No. PCT/CN2020/140705 by LI et al. entitled “SIGNALING OF GRADIENT VECTORS FOR FEDERATED LEARNING IN A WIRELESS COMMUNICATIONS SYSTEM,” filed Dec. 29, 2023, which is assigned to the assignee hereof, and which is expressly incorporated by reference in its entirety herein.

### FIELD OF TECHNOLOGY

The following relates to wireless communications, including signaling of gradient vectors for federated learning in a wireless communications system.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal frequency division multiple access (OFDMA), or discrete Fourier transform spread orthogonal frequency division multiplexing (DFT-S-OFDM). A wireless multiple-access communications system may include one or more base stations or one or more network access nodes, each simultaneously supporting communication for multiple communication devices, which may be otherwise known as user equipment (UE).

### SUMMARY

The described techniques relate to improved methods, systems, devices, and apparatuses that support signaling of gradient vectors for federated learning in a wireless communications system. The described techniques relate to improved methods, systems, devices, and apparatuses that support signaling design for compressed gradient vector communications in a machine learning system that utilizes federated learning in which stochastic gradients from multiple edge devices (e.g., multiple user equipment (UE) devices) are combined into a global model. Various described techniques are provided for a UE and a base station to implement communication of one or more gradient vectors that quantize a local stochastic gradient at the UE. In some cases, the base station may provide the UE with configuration information for reporting a set of compressed gradient vectors in which each vector of the set of compressed gradient vectors is associated with a different stage of a multi-stage compression procedure for a local stochastic gradient vector associated with a machine learning algorithm.

The configuration information may include, for example, one or more partitioning parameters, one or more quantization codebooks for quantizing one or more parameters of the local stochastic gradient vector (e.g., for indicating a norm, a block gradient vector for a number of blocks of the local stochastic gradient vector, a hinge vector associated with each block of the local stochastic gradient vector, or any combinations thereof), one or more bit allocation scheme parameters for reporting the set of compressed gradient vectors, or any combinations thereof. Based on the configuration information, the UE may generate the set of compressed gradient vectors, and transmit the set of vectors to the base station. In some cases, the base station may indicate one or more updated model values responsive to the set of compressed gradient vectors (e.g., updated values for one or more components that are mapped to a neural network (NN) component), for use in subsequent communications between the UE and the base station.

A method for wireless communication at a user equipment (UE) is described. The method may include receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm, identifying each compressed gradient vector of the set of multiple compressed gradient vectors based on the machine learning algorithm at the UE and the configuration information, and transmitting each compressed gradient vector of the set of multiple compressed gradient vectors to the base station based on the configuration information.

An apparatus for wireless communication at a UE is described. The apparatus may include a processor, memory in electronic communication with the processor, and instructions stored in the memory. The instructions may be executable by the processor to cause the apparatus to receive, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm, identify each compressed gradient vector of the set of multiple compressed gradient vectors based on the machine learning algorithm at the UE and the configuration information, and transmit each compressed gradient vector of the set of multiple compressed gradient vectors to the base station based on the configuration information.

Another apparatus for wireless communication at a UE is described. The apparatus may include means for receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm, means for identifying each compressed gradient vector of the set of multiple compressed gradient vectors based on the machine learning algorithm at the UE and the configuration information, and means for transmitting each compressed gradient vector of the set of multiple compressed gradient vectors to the base station based on the configuration information.

A non-transitory computer-readable medium storing code for wireless communication at a UE is described. The code may include instructions executable by a processor to receive, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm, identify each compressed gradient vector of the set of multiple compressed gradient vectors based on the machine learning algorithm at the UE and the configuration information, and transmit each compressed gradient vector of the set of multiple compressed gradient vectors to the base station based on the configuration information.

In some examples of the method, apparatuses, and non-transitory computer-readable medium described herein, the receiving the configuration information may include operations, features, means, or instructions for receiving one or more partitioning parameters associated with the local stochastic gradient vector, receiving a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof, and receiving one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof.

In some examples of the method, apparatuses, and non-transitory computer-readable medium described herein, the one or more partitioning parameters indicate a number of blocks of a stochastic gradient that is to be included in the local stochastic gradient vector, a vector length of each block of the number of blocks, or any combinations thereof and the set of multiple quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

In some examples of the method, apparatuses, and non-transitory computer-readable medium described herein, the receiving the configuration information may include operations, features, means, or instructions for receiving one or more configuration parameters in radio resource control signaling, in a medium access control (MAC) control element, in downlink control information, in one or more higher layer or application layer communications, or any combinations thereof.

Some examples of the method, apparatuses, and non-transitory computer-readable medium described herein may further include operations, features, means, or instructions for selecting, based on the configuration information and the local stochastic gradient vector, a first partitioning parameter of the one or more partitioning parameters, one or more quantization codebooks of the set of multiple quantization codebooks, and a first bit allocation scheme parameter of the one or more bit allocation scheme parameters and transmitting, to the base station, an indication of the selected first partitioning parameter, the one or more quantization codebooks, and the first bit allocation scheme parameter using a set of bits that is configured by the configuration information. In some examples of the method, apparatuses, and non-transitory computer-readable medium described herein, the set of bits is explicitly indicated by the base station or identified based on an uplink resource for reporting the set of multiple compressed gradient vectors, and where an order of bits within a payload that provides the set of multiple compressed gradient vectors is indicated in the configuration information or is predefined at the UE. In some examples of the method, apparatuses, and non-transitory computer-readable medium described herein, the machine learning algorithm provides a set of multiple rounds of compressed gradient vector reporting, and where the configuration information is provided separately for each of the plurality or rounds, or the configuration information is applied to each of the set of multiple rounds.

In some examples of the method, apparatuses, and non-transitory computer-readable medium described herein, the set of multiple compressed gradient vectors is determined based on a partitioning parameter for the local stochastic gradient vector, one or more quantization codebooks associated with each of the set of multiple compressed gradient vectors, and a payload format for reporting the set of multiple compressed gradient vectors and where the partitioning parameter, the one or more quantization codebooks, and the payload format are provided with the configuration information, are selected from a set of available parameters, codebooks, and payload formats that are provided by the base station, or are determined entirely or partly by the UE. In some examples of the method, apparatuses, and non-transitory computer-readable medium described herein, the configuration information further indicates a format for a block-quantized gradient report that includes a set of multiple parts for reporting the set of multiple compressed gradient vectors, and a quantity of bits in each of the set of multiple parts. In some examples of the method, apparatuses, and non-transitory computer-readable medium described herein, at least one of the set of multiple parts has a different quantity of bits than one or more other of the set of multiple parts, and where the quantity of bits of each of the set of multiple parts is provided by the configuration information or is predefined at the UE.

In some examples of the method, apparatuses, and non-transitory computer-readable medium described herein, the block-quantized gradient report includes a first part that indicates a quantized value of a norm of the local stochastic gradient vector that is based on a first bit allocation for an associated scalar quantizer, a second part that indicates quantized values of a set of multiple normalized block gradients of the local stochastic gradient vector that is based on a second bit allocation for a uniform and even Grassmannian quantizer, and a third part that indicates quantized values of a hinge vector associated with the set of multiple normalized block gradients that is based on a third bit allocation for a positive Grassmannian quantizer.

Some examples of the method, apparatuses, and non-transitory computer-readable medium described herein may further include operations, features, means, or instructions for receiving, from the base station, an indication of one or more uplink resources for transmission of each of the set of multiple compressed gradient vectors, where the indication may be provided in one or more of uplink control information, a medium access control (MAC) control element, in radio resource control signaling, in one or more upper layer messages, or any combinations thereof, and where the set of multiple compressed gradient vectors may be transmitted using one or more different uplink resources provided in one or more different uplink grants.

In some examples of the method, apparatuses, and non-transitory computer-readable medium described herein, the one or more different uplink grants include a set of multiple configured uplink grants for uplink shared channel transmissions, and where different compressed gradient vectors of the set of multiple compressed gradient vectors may be transmitted using different configured uplink grants of the set of multiple configured uplink grants, and where and the set of multiple configured uplink grants are each associated with different compressed gradient vectors based on an indication provided in the configuration information, a predefined association at the UE, or based on a determination made at the UE and reported to the base station.

A method for wireless communication at a base station is described. The method may include transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm, initiating the machine learning algorithm at the set of multiple UEs as part of a federated machine learning procedure, and receiving, from each of the set of multiple UEs, the set of multiple compressed gradient vectors based on the machine learning algorithm at each UE and the configuration information.

An apparatus for wireless communication at a base station is described. The apparatus may include a processor, memory in electronic communication with the processor, and instructions stored in the memory. The instructions may be executable by the processor to cause the apparatus to transmit, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm, initiate the machine learning algorithm at the set of multiple UEs as part of a federated machine learning procedure, and receive, from each of the set of multiple UEs, the set of multiple compressed gradient vectors based on the machine learning algorithm at each UE and the configuration information.

Another apparatus for wireless communication at a base station is described. The apparatus may include means for transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm, means for initiating the machine learning algorithm at the set of multiple UEs as part of a federated machine learning procedure, and means for receiving, from each of the set of multiple UEs, the set of multiple compressed gradient vectors based on the machine learning algorithm at each UE and the configuration information.

A non-transitory computer-readable medium storing code for wireless communication at a base station is described. The code may include instructions executable by a processor to transmit, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm, initiate the machine learning algorithm at the set of multiple UEs as part of a federated machine learning procedure, and receive, from each of the set of multiple UEs, the set of multiple compressed gradient vectors based on the machine learning algorithm at each UE and the configuration information.

In some examples of the method, apparatuses, and non-transitory computer-readable medium described herein, the transmitting the configuration information may include operations, features, means, or instructions for transmitting one or more partitioning parameters associated with the local stochastic gradient vector, transmitting a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof, and transmitting one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof.

In some examples of the method, apparatuses, and non-transitory computer-readable medium described herein, the one or more partitioning parameters indicate a number of blocks of a stochastic gradient that are to be included in the local stochastic gradient vector, a vector length of each block of the number of blocks, or any combinations thereof and the set of multiple quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

Some examples of the method, apparatuses, and non-transitory computer-readable medium described herein may further include operations, features, means, or instructions for configuring the set of multiple UEs to select, based on the configuration information and the associated local stochastic gradient vector, a first partitioning parameter of the one or more partitioning parameters, one or more quantization codebooks of the set of multiple quantization codebooks, and a first bit allocation scheme parameter of the one or more bit allocation scheme parameters, configuring the set of multiple UEs to report the selected parameter, codebooks, and allocation scheme parameter, using a set of bits, and receiving, from the set of multiple UEs, the set of bits that provide associated indications of the selected first partitioning parameter, the one or more quantization codebooks, and the first bit allocation scheme parameter.

In some examples of the method, apparatuses, and non-transitory computer-readable medium described herein, the set of multiple compressed gradient vectors is determined based on a partitioning parameter for the local stochastic gradient vector, one or more quantization codebooks associated with each of the set of multiple compressed gradient vectors, and a payload format for reporting the set of multiple compressed gradient vectors and where the partitioning parameter, the one or more quantization codebooks, and the payload format are provided with the configuration information, are selected from a set of available parameters, codebooks, and payload formats that are provided by the base station, or are determined entirely or partly by the UE.

In some examples of the method, apparatuses, and non-transitory computer-readable medium described herein, the configuration information further indicates a format for a block-quantized gradient report that includes a set of multiple parts for reporting the set of multiple compressed gradient vectors, and a quantity of bits in each of the set of multiple parts. In some examples of the method, apparatuses, and non-transitory computer-readable medium described herein, at least one of the set of multiple parts may have a different quantity of bits than one or more other of the set of multiple parts, and where the quantity of bits of each of the set of multiple parts is provided by the configuration information or is predefined at the UE.

In some examples of the method, apparatuses, and non-transitory computer-readable medium described herein, the block-quantized gradient report includes a first part that indicates a quantized value of a norm of the local stochastic gradient vector that is based on a first bit allocation for an associated scalar quantizer, a second part that indicates quantized values of a set of multiple normalized block gradients of the local stochastic gradient vector that is based on a second bit allocation for a uniform and even Grassmannian quantizer, and a third part that indicates quantized values of a hinge vector associated with the set of multiple normalized block gradients that is based on a third bit allocation for a positive Grassmannian quantizer.

Some examples of the method, apparatuses, and non-transitory computer-readable medium described herein may further include operations, features, means, or instructions for transmitting, to each of the set of multiple UEs, an indication of one or more uplink resources for transmission of each of the set of multiple compressed gradient vectors, where the indication may be provided in one or more of uplink control information, a medium access control (MAC) control element, in radio resource control signaling, in one or more upper layer messages, or any combinations thereof, and where the set of multiple compressed gradient vectors is transmitted using one or more different uplink resources provided in one or more different uplink grants.

In some examples of the method, apparatuses, and non-transitory computer-readable medium described herein, the one or more different uplink grants include a set of multiple configured uplink grants for uplink shared channel transmissions, and where different compressed gradient vectors of the set of multiple compressed gradient vectors are transmitted using different configured uplink grants of the set of multiple configured uplink grants, and where and the set of multiple configured uplink grants are each associated with different compressed gradient vectors based on an indication provided in the configuration information, a predefined association at the UE, or based on a determination made at the UE and reported to the base station.

### BRIEF DESCRIPTION OF THE DRAWINGS

FIG. 1 illustrates an example of a wireless communications system that supports signaling of gradient vectors for federated learning in a wireless communications system in accordance with aspects of the present disclosure.

FIG. 2 illustrates an example of a portion of a wireless communications system that supports signaling of gradient vectors for federated learning in a wireless communications system in accordance with aspects of the present disclosure.

FIG. 3 illustrates an example of a wireless communications system with federated learning that supports signaling of gradient vectors for federated learning in a wireless communications system in accordance with aspects of the present disclosure.

FIG. 4 illustrates an example of a block-wise gradient vector quantization scheme that supports signaling of gradient vectors for federated learning in a wireless communications system in accordance with aspects of the present disclosure.

FIG. 5 illustrates an example of a process flow that supports signaling of gradient vectors for federated learning in a wireless communications system in accordance with aspects of the present disclosure.

FIGS. 6 and 7 show block diagrams of devices that support signaling of gradient vectors for federated learning in a wireless communications system in accordance with aspects of the present disclosure.

FIG. 8 shows a block diagram of a communications manager that supports signaling of gradient vectors for federated learning in a wireless communications system in accordance with aspects of the present disclosure.

FIG. 9 shows a diagram of a system including a device that supports signaling of gradient vectors for federated learning in a wireless communications system in accordance with aspects of the present disclosure.

FIGS. 10 and 11 show block diagrams of devices that support signaling of gradient vectors for federated learning in a wireless communications system in accordance with aspects of the present disclosure.

FIG. 12 shows a block diagram of a communications manager that supports signaling of gradient vectors for federated learning in a wireless communications system in accordance with aspects of the present disclosure.

FIG. 13 shows a diagram of a system including a device that supports signaling of gradient vectors for federated learning in a wireless communications system in accordance with aspects of the present disclosure.

FIGS. 14 through 21 show flowcharts illustrating methods that support signaling of gradient vectors for federated learning in a wireless communications system in accordance with aspects of the present disclosure.

### DETAILED DESCRIPTION

In some wireless communications systems, a wireless device (e.g., a user equipment (UE) or a base station) may utilize machine learning models (e.g., a neural network (NN) based machine learning model) in which one or more components may be configured using machine learning for end-to-end communications. Such configuration may include NN-based machine learning model configurations at a transmitter that provide one or more of encoding, modulation, or precoding functions, and NN-based configurations at a receiver that provide one or more of synchronization, channel estimation, detection, demodulation, or decoding functions. One or more components that utilize machine learning for such functions may be used to replace one, some, or all transmit/receive modules at a device. In some cases, end-to-end communications using machine learning components (e.g., NN-based components) may be referred to as complete end-to-end autoencoders. An autoencoder may be an example of a NN-system that modulates a message and demodulates a message, along with other transmission and receive functions. For example, the autoencoder may include an NN-based encoder and an NN-based decoder, and the autoencoder may train the NNs for compressing messages for efficient transmission and decompressing messages for accurate determination of the compressed information respectively. As part of the autoencoder design, the NN-based transmission components and NN-based receive components may be trained using a federated learning technique in which edge devices (e.g., UEs) provide training information that is aggregated at an edge server (e.g., a base station) and used to update the machine learning model.

In some cases, the machine learning model may have relatively high dimensions, may include a relatively large number of machine learning components, or any combinations thereof. For example, a residual neural network (ResNet) may include a number of layers (e.g., 50 layers) that may each have a number of nodes in which input and output relations between the layers and nodes may be trained in accordance with a machine learning algorithm. Due to the potential relatively large number of layers, and nodes within layers, a relatively large amount of data may need to be communicated as part of a machine learning procedure. For example, a 50 layer ResNet used in an end-to-end autoencoder may comprise about 26 million parameters after training. Accordingly, efficient techniques for communicating such training information may be desirable.

In some cases, federated learning may be used for training of machine learning models. In such techniques, a number of edge devices (e.g., UEs) may provide local gradients to an edge server for inclusion in the machine learning model. The edge server may trigger local training at the edge device, which may then measure one or more parameters (e.g., local channel quality parameters) and generate a local model or local gradient that is transmitted to the edge server (e.g., the uploaded parameters can be parameters in a ResNet or gradients to derive the ResNet). The edge server may aggregate multiple local models or local gradients and update a global model at the edge server (e.g., using parameter or gradient averaging). The edge server may then provide an updated global model or NN-weights to the edge devices. Federated learning models may provide relatively fast access to real-time or near-real-time data generated at edge devices, which may allow for relatively fast training of the machine learning models. Further, such federated learning may consume relatively fewer radio resources and have lower delay, due to multiple edge devices providing their local gradient or local model. Further, as the edge devices may not need to provide raw data, such federated learning techniques may provide enhanced privacy. However, as discussed, in the event that the machine learning models start to use a relatively large number of layers and associated nodes, signaling local gradients or models may still consume a relatively large amount of resources. Various aspects of the present disclosure provide for configuration and signaling of local gradients by an edge device (e.g., a UE) using a number of compression vectors generated from a multi-stage compression technique.

In some cases, a UE may be configured or indicated by a base station with configuration information for reporting of block-quantized gradients for federated learning. In some cases, the base station may provide the UE with configuration information for reporting a set of compressed gradient vectors in which each vector of the set of compressed gradient vectors is associated with a different stage of a multi-stage compression procedure for a local stochastic gradient vector associated with a federated machine learning algorithm. The configuration information may include, for example, one or more partitioning parameters, one or more quantization codebooks for quantizing one or more parameters of the local stochastic gradient vector (e.g., for indicating a norm, a block gradient vector for a number of blocks of the local stochastic gradient vector, a hinge vector associated with each block of the local stochastic gradient vector, or any combinations thereof), one or more bit allocation scheme parameters for reporting the set of compressed gradient vectors, or any combinations thereof. Based on the configuration information, the UE may generate the set of compressed gradient vectors, and transmit the set of vectors to the base station.

Such techniques may allow the UE to report compressed gradient vectors using selected codebooks according to identified partitioning schemes and bit allocations, and in some cases, in a multi-stage manner with tractable payload sizes that can be identified by the base station. In some cases, the configuration information may be carried in radio resource control (RRC) signaling, in a medium access control (MAC) control element (CE), in control information (e.g., downlink control information (DCI)), in a physical downlink control channel (PDCCH) communication, or any combinations thereof. Such techniques may allow for communication of federated learning information using reduced wireless resources, which may help to reduce wireless overhead associated with machine learning algorithms. Further, such techniques may enhance network efficiency and reliability through communication of federated learning information that may be used to update machine learning algorithms based on local channel conditions at a number of different UEs.

Aspects of the disclosure are initially described in the context of wireless communications systems. Additional aspects of the disclosure are described with reference to federated learning configurations and process flows. Aspects of the disclosure are further illustrated by and described with reference to apparatus diagrams, system diagrams, and flowcharts that relate to signaling of gradient vectors for federated learning in a wireless communications system.

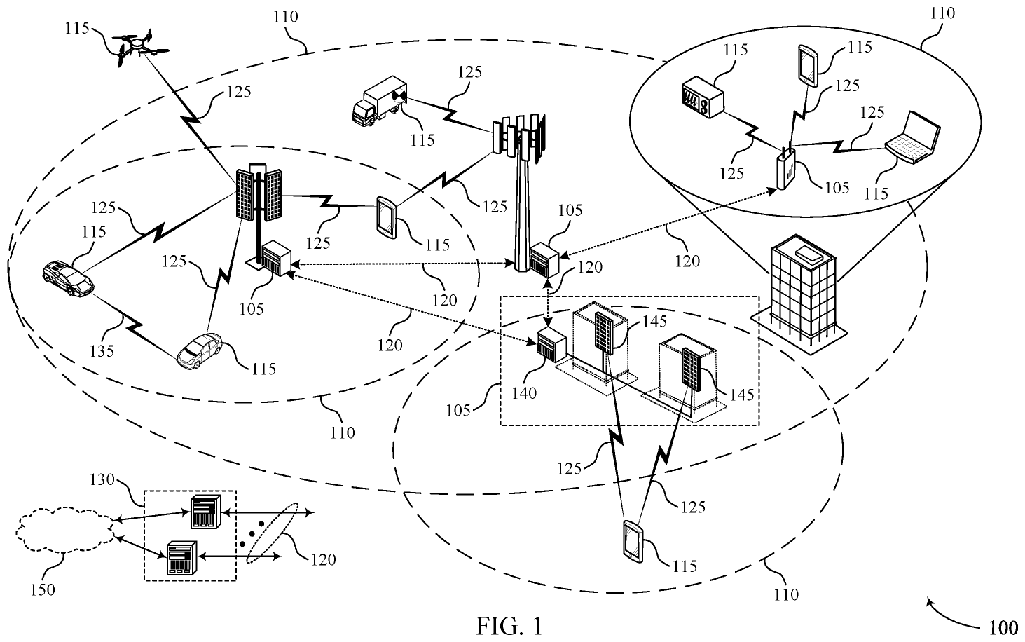

FIG. 1 illustrates an example of a wireless communications system 100 that supports signaling of gradient vectors for federated learning in a wireless communications system in accordance with aspects of the present disclosure. The wireless communications system 100 may include one or more base stations 105, one or more UEs 115, and a core network 130. In some examples, the wireless communications system 100 may be a Long Term Evolution (LTE) network, an LTE-Advanced (LTE-A) network, an LTE-A Pro network, or a New Radio (NR) network. In some examples, the wireless communications system 100 may support enhanced broadband communications, ultra-reliable (e.g., mission critical) communications, low latency communications, communications with low-cost and low-complexity devices, or any combination thereof.

The base stations 105 may be dispersed throughout a geographic area to form the wireless communications system 100 and may be devices in different forms or having different capabilities. The base stations 105 and the UEs 115 may wirelessly communicate via one or more communication links 125. Each base station 105 may provide a coverage area 110 over which the UEs 115 and the base station 105 may establish one or more communication links 125. The coverage area 110 may be an example of a geographic area over which a base station 105 and a UE 115 may support the communication of signals according to one or more radio access technologies.

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be able to communicate with various types of devices, such as other UEs 115, the base stations 105, or network equipment (e.g., core network nodes, relay devices, integrated access and backhaul (IAB) nodes, or other network equipment), as shown in FIG. 1.

The base stations 105 may communicate with the core network 130, or with one another, or both. For example, the base stations 105 may interface with the core network 130 through one or more backhaul links 120 (e.g., via an S1, N2, N3, or other interface). The base stations 105 may communicate with one another over the backhaul links 120 (e.g., via an X2, Xn, or other interface) either directly (e.g., directly between base stations 105), or indirectly (e.g., via core network 130), or both. In some examples, the backhaul links 120 may be or include one or more wireless links.

One or more of the base stations 105 described herein may include or may be referred to by a person having ordinary skill in the art as a base transceiver station, a radio base station, an access point, a radio transceiver, a NodeB, an eNodeB (eNB), a next-generation NodeB or a giga-NodeB (either of which may be referred to as a gNB), a Home NodeB, a Home eNodeB, or other suitable terminology.

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the base stations 105 and the network equipment including macro eNBs or gNBs, small cell eNBs or gNBs, or relay base stations, among other examples, as shown in FIG. 1.

The UEs 115 and the base stations 105 may wirelessly communicate with one another via one or more communication links 125 over one or more carriers. The term “carrier” may refer to a set of radio frequency spectrum resources having a defined physical layer structure for supporting the communication links 125. For example, a carrier used for a communication link 125 may include a portion of a radio frequency spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers.

Signal waveforms transmitted over a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may consist of one symbol period (e.g., a duration of one modulation symbol) and one subcarrier, where the symbol period and subcarrier spacing are inversely related. The number of bits carried by each resource element may depend on the modulation scheme (e.g., the order of the modulation scheme, the coding rate of the modulation scheme, or both). Thus, the more resource elements that a UE 115 receives and the higher the order of the modulation scheme, the higher the data rate may be for the UE 115. A wireless communications resource may refer to a combination of a radio frequency spectrum resource, a time resource, and a spatial resource (e.g., spatial layers or beams), and the use of multiple spatial layers may further increase the data rate or data integrity for communications with a UE 115.

One or more numerologies for a carrier may be supported, where a numerology may include a subcarrier spacing (Δf) and a cyclic prefix. A carrier may be divided into one or more BWPs having the same or different numerologies. In some examples, a UE 115 may be configured with multiple BWPs. In some examples, a single BWP for a carrier may be active at a given time and communications for the UE 115 may be restricted to one or more active BWPs.

The time intervals for the base stations 105 or the UEs 115 may be expressed in multiples of a basic time unit which may, for example, refer to a sampling period of Tₛ=1/(Δfₘₐₓ·N_{f}) seconds, where Δfₘₐₓ may represent the maximum supported subcarrier spacing, and N_{f} may represent the maximum supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively numbered subframes or slots, and each subframe or slot may have the same duration. In some examples, a frame may be divided (e.g., in the time domain) into subframes, and each subframe may be further divided into a number of slots. Alternatively, each frame may include a variable number of slots, and the number of slots may depend on subcarrier spacing. Each slot may include a number of symbol periods (e.g., depending on the length of the cyclic prefix prepended to each symbol period). In some wireless communications systems 100, a slot may further be divided into multiple mini-slots containing one or more symbols. Excluding the cyclic prefix, each symbol period may contain one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., the number of symbol periods in a TTI) may be variable. Additionally or alternatively, the smallest scheduling unit of the wireless communications system 100 may be dynamically selected (e.g., in bursts of shortened TTIs (sTTIs)).

Physical channels may be multiplexed on a carrier according to various techniques. A physical control channel and a physical data channel may be multiplexed on a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a number of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to a number of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a base station 105 may be movable and therefore provide communication coverage for a moving geographic coverage area 110. In some examples, different geographic coverage areas 110 associated with different technologies may overlap, but the different geographic coverage areas 110 may be supported by the same base station 105. In other examples, the overlapping geographic coverage areas 110 associated with different technologies may be supported by different base stations 105. The wireless communications system 100 may include, for example, a heterogeneous network in which different types of the base stations 105 provide coverage for various geographic coverage areas 110 using the same or different radio access technologies.

The wireless communications system 100 may be configured to support ultra-reliable communications or low-latency communications, or various combinations thereof. For example, the wireless communications system 100 may be configured to support ultra-reliable low-latency communications (URLLC) or mission critical communications. The UEs 115 may be designed to support ultra-reliable, low-latency, or critical functions (e.g., mission critical functions). Ultra-reliable communications may include private communication or group communication and may be supported by one or more mission critical services such as mission critical push-to-talk (MCPTT), mission critical video (MCVideo), or mission critical data (MCData). Support for mission critical functions may include prioritization of services, and mission critical services may be used for public safety or general commercial applications. The terms ultra-reliable, low-latency, mission critical, and ultra-reliable low-latency may be used interchangeably herein.

In some examples, a UE 115 may also be able to communicate directly with other UEs 115 over a device-to-device (D2D) communication link 135 (e.g., using a peer-to-peer (P2P) or D2D protocol). One or more UEs 115 utilizing D2D communications may be within the geographic coverage area 110 of a base station 105. Other UEs 115 in such a group may be outside the geographic coverage area 110 of a base station 105 or be otherwise unable to receive transmissions from a base station 105. In some examples, groups of the UEs 115 communicating via D2D communications may utilize a one-to-many (1:M) system in which each UE 115 transmits to every other UE 115 in the group. In some examples, a base station 105 facilitates the scheduling of resources for D2D communications. In other cases, D2D communications are carried out between the UEs 115 without the involvement of a base station 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the base stations 105 associated with the core network 130. User IP packets may be transferred through the user plane entity, which may provide IP address allocation as well as other functions. The user plane entity may be coupled to IP services 150 for one or more network operators. The IP services 150 may include access to the Internet, Intranet(s), an IP Multimedia Subsystem (IMS), or a Packet-Switched Streaming Service.

Some of the network devices, such as a base station 105, may include subcomponents such as an access network entity 140, which may be an example of an access node controller (ANC). Each access network entity 140 may communicate with the UEs 115 through one or more other access network transmission entities 145, which may be referred to as radio heads, smart radio heads, or transmission/reception points (TRPs). Each access network transmission entity 145 may include one or more antenna panels. In some configurations, various functions of each access network entity 140 or base station 105 may be distributed across various network devices (e.g., radio heads and ANCs) or consolidated into a single network device (e.g., a base station 105).

The wireless communications system 100 may operate using one or more frequency bands, typically in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. The UHF waves may be blocked or redirected by buildings and environmental features, but the waves may penetrate structures sufficiently for a macro cell to provide service to the UEs 115 located indoors. The transmission of UHF waves may be associated with smaller antennas and shorter ranges (e.g., less than 100 kilometers) compared to transmission using the smaller frequencies and longer waves of the high frequency (HF) or very high frequency (VHF) portion of the spectrum below 300 MHz.

The wireless communications system 100 may utilize both licensed and unlicensed radio frequency spectrum bands. For example, the wireless communications system 100 may employ License Assisted Access (LAA), LTE-Unlicensed (LTE-U) radio access technology, or NR technology in an unlicensed band such as the 5 GHz industrial, scientific, and medical (ISM) band. When operating in unlicensed radio frequency spectrum bands, devices such as the base stations 105 and the UEs 115 may employ carrier sensing for collision detection and avoidance. In some examples, operations in unlicensed bands may be based on a carrier aggregation configuration in conjunction with component carriers operating in a licensed band (e.g., LAA). Operations in unlicensed spectrum may include downlink transmissions, uplink transmissions, P2P transmissions, or D2D transmissions, among other examples.

A base station 105 or a UE 115 may be equipped with multiple antennas, which may be used to employ techniques such as transmit diversity, receive diversity, multiple-input multiple-output (MIMO) communications, or beamforming. The antennas of a base station 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a base station 105 may be located in diverse geographic locations. A base station 105 may have an antenna array with a number of rows and columns of antenna ports that the base station 105 may use to support beamforming of communications with a UE 115. Likewise, a UE 115 may have one or more antenna arrays that may support various MIMO or beamforming operations. Additionally or alternatively, an antenna panel may support radio frequency beamforming for a signal transmitted via an antenna port.

Beamforming, which may also be referred to as spatial filtering, directional transmission, or directional reception, is a signal processing technique that may be used at a transmitting device or a receiving device (e.g., a base station 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating at particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The wireless communications system 100 may be a packet-based network that operates according to a layered protocol stack. In the user plane, communications at the bearer or Packet Data Convergence Protocol (PDCP) layer may be IP-based. A Radio Link Control (RLC) layer may perform packet segmentation and reassembly to communicate over logical channels. A Medium Access Control (MAC) layer may perform priority handling and multiplexing of logical channels into transport channels. The MAC layer may also use error detection techniques, error correction techniques, or both to support retransmissions at the MAC layer to improve link efficiency. In the control plane, the Radio Resource Control (RRC) protocol layer may provide establishment, configuration, and maintenance of an RRC connection between a UE 115 and a base station 105 or a core network 130 supporting radio bearers for user plane data. At the physical layer, transport channels may be mapped to physical channels.

The UEs 115 and the base stations 105 may support retransmissions of data to increase the likelihood that data is received successfully. Hybrid automatic repeat request (HARQ) feedback is one technique for increasing the likelihood that data is received correctly over a communication link 125. HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., low signal-to-noise conditions). In some examples, a device may support same-slot HARQ feedback, where the device may provide HARQ feedback in a specific slot for data received in a previous symbol in the slot. In other cases, the device may provide HARQ feedback in a subsequent slot, or according to some other time interval.

In the wireless communications system 100, a UE 115 and a base station 105 may implement NN-based communications in which an end-to-end autoencoder may be implemented for wireless communications. In some cases, federated learning may be used to update machine-learning models in order to further enhance communications efficiency. In some cases, the base station 105 may provide the UE 115 with configuration information for reporting of one or more gradient vectors that quantize a local stochastic gradient at the UE 115. In some cases, the configuration information may provide parameters for reporting a set of compressed gradient vectors in which each vector of the set of compressed gradient vectors is associated with a different stage of a multi-stage compression procedure for a local stochastic gradient vector associated with a machine learning algorithm. The configuration information may include, for example, one or more partitioning parameters, one or more quantization codebooks for quantizing one or more parameters of the local stochastic gradient vector, one or more bit allocation scheme parameters for reporting the set of compressed gradient vectors, or any combinations thereof. Based on the configuration information, the UE 115 may generate the set of compressed gradient vectors, and transmit the set of vectors to the base station 105. In some cases, the base station 105 may indicate one or more updated model values responsive to the set of compressed gradient vectors (e.g., updated values for one or more components that are mapped to a NN component), for use in subsequent communications between the UE 115 and the base station 105.

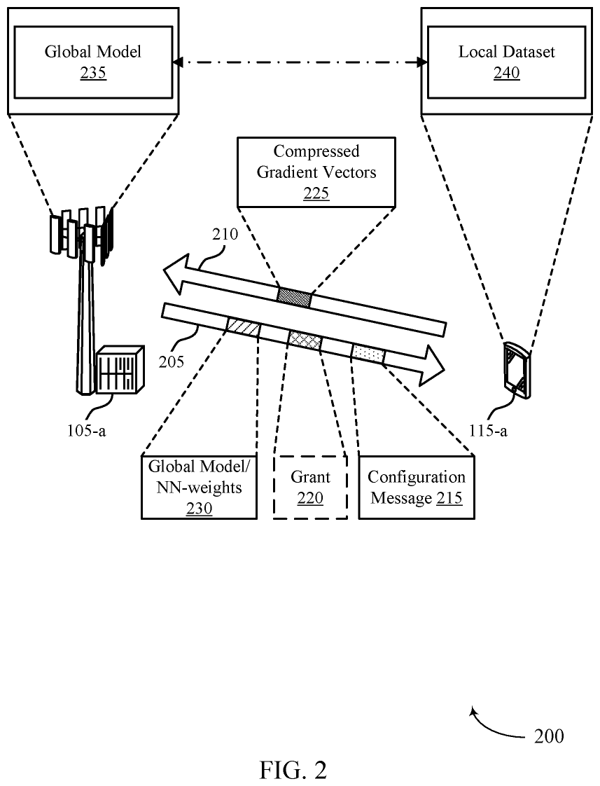

FIG. 2 illustrates an example of a wireless communications system 200 that supports signaling of gradient vectors for federated learning in a wireless communications system in accordance with aspects of the present disclosure. The wireless communications system 200 may include base station 105-a and UE 115-a, which may be examples of the corresponding devices as described herein. Base station 105-a and UE 115-a may communicate via a downlink communication link 205 and an uplink communication link 210. The wireless communications system 200 may support federated learning (e.g., for NN-based communications) between base station 105 a and UE 115 a, which may improve spectral efficiency and signaling overhead.

In some cases, base station 105-a may transmit a configuration message 215 that configures the UE 115-a for reporting a set of compressed gradient vectors 225. Each vector of the set of compressed gradient vectors 225 may be associated with a different stage of a multi-stage compression procedure for a local stochastic gradient vector associated with a local dataset 240 that is generated at the UE 115-a as part of a federated learning process. In some cases, the compressed gradient vectors 225 may be reported in an uplink communication that is transmitted responsive to a grant 220 provided by the base station 105-a (e.g., an uplink grant that is provided by a DCI that triggers a training procedure). The base station 105-a, based on the set of compressed gradient vectors 225, may update a global model 235 of the machine learning algorithm (e.g., NN autoencoder) and transmit information for the global model or NN-weights 230 to the UE 115-a, which may use this information to update a machine learning algorithm (e.g., NN autoencoder) at the UE 115-a.

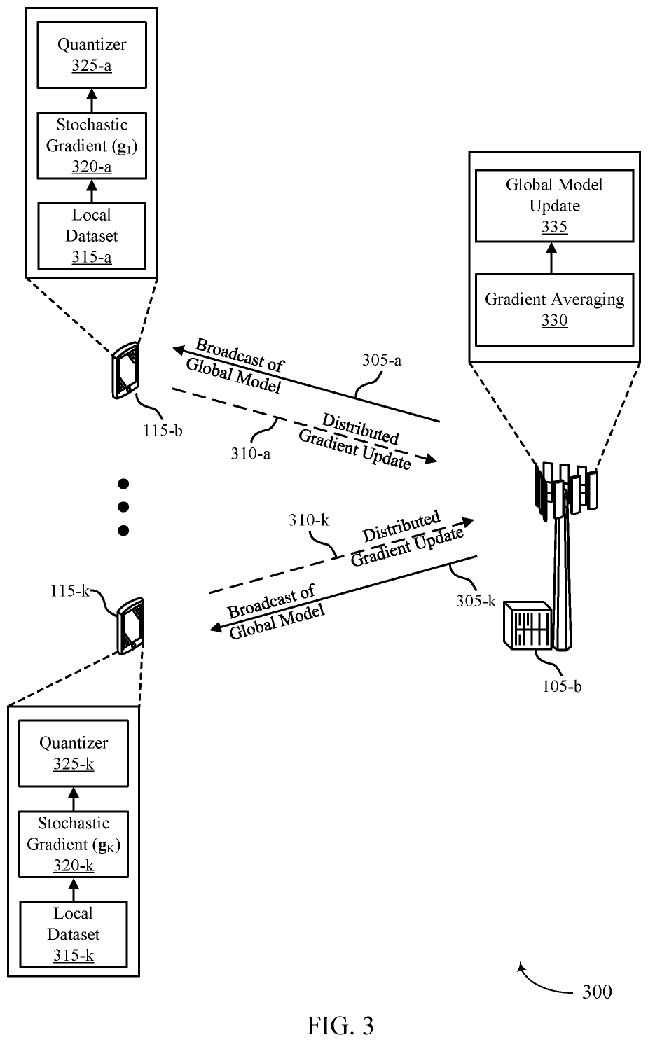

In some cases, the set of compressed gradient vectors 225 may be used to signal block-quantized gradients from the local dataset 240 for federated learning. The configuration message 215 may provide information related to various aspects for reporting the block-quantized gradients, that may assist the UE 115-a in determining codebooks, partitioning schemes, bit allocations, or any combinations thereof, of one or more of the compressed gradient vectors 225. In some cases, the UE 115-a may select one or more parameters for the reporting, and the base station 105-a may indicate how to report selected codebooks, partitioning schemes, and bit allocation (e.g., potentially in a multi-stage manner, with tractable payload sizes that can be identified by the base station 105-a. In some cases, the configuration message 215 may be provided in RRC signaling, in a medium access control (MAC) control element (CE), in downlink control information (DCI), or any combinations thereof, that indicates at least one of partitioning parameters for indicating block-quantized gradients, quantizer codebook selection parameters, bit allocation parameters, or any combinations thereof. FIGS. 3-5 provide additional details related to such configuration parameters and for reporting block-quantized gradients in accordance with various aspects of the present disclosure.

FIG. 3 illustrates an example of a wireless communications system with federated learning 300 that supports signaling of gradient vectors for federated learning in a wireless communications system in accordance with aspects of the present disclosure. The wireless communications system with federated learning 300 may include base station 105-b which may be an example of an edge server and a number of UEs 115, including a first UE 115-b through a k-th UE 115-k, which may be examples an edge device. The base station 105-b and UEs 115 may be examples of the corresponding devices as described herein. Base station 105-b and UEs 115 may communicate via downlink communication links 305 and an uplink communication links 310. The federated learning provided using the UEs 115 reporting of local gradients may allow for training of a machine learning model at the base station 105-b, which may improve spectral efficiency and signaling overhead.

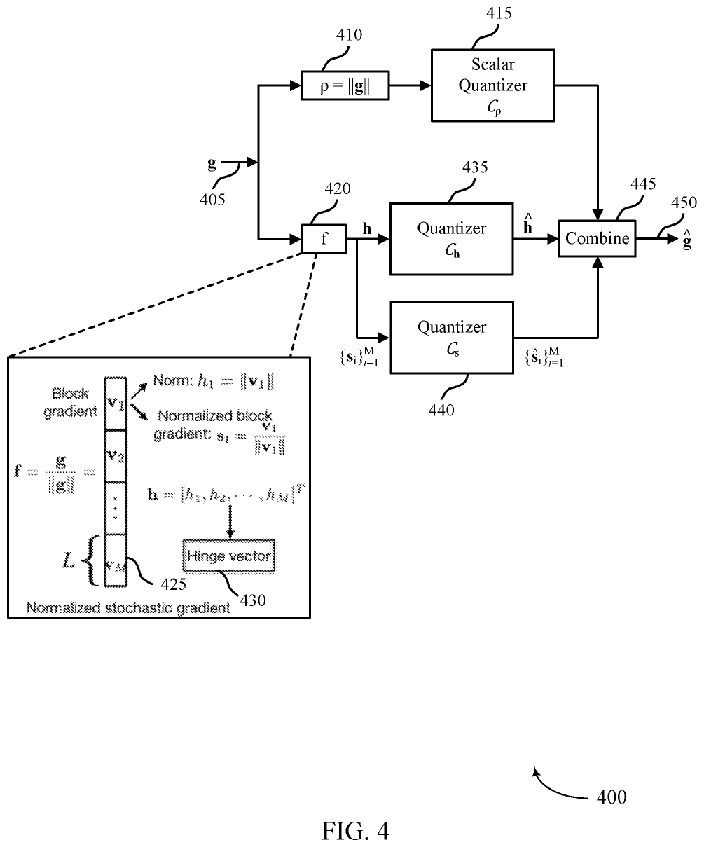

In this example, each UE 115 may be triggered for local training by the base station 105-a (e.g., based on configuration and triggering indications provided by the base station 105-b such as discussed herein). Based on the triggering of the local training, each UE 115 may generate a local dataset 315 (e.g., based on one or more channel measurements made at the UE 115, one or more beam measurements made at the UE 115, prior successful or unsuccessful decoding of communications at the UE 115, etc.). Based on the local dataset each UE 115 may determine a local stochastic gradient 320 (e.g., g₁ through gₖ). The local stochastic gradients 320 may be determined based on a local model at each UE 115 that is based on a broadcast of the global model in downlink communication links 305, and may be transmitted to the base station 105-b via the uplink communication links 310. The uploaded parameters may be, for example, parameters for a ResNet, or gradients to derive a ResNet. In some aspects, the UEs 115 may report the parameters as distributed gradient updates with compressed gradient vectors that are determined based on a quantizer 325 function at each UE 115. The base station 105-b may aggregate the received local models or gradients at gradient averaging function 330, and the aggregated information provided to a global model update 335 function. The aggregation may be, for example, parameter/gradient averaging, or other aggregation of local information as part of a federated learning procedure. Upon updating the global model, the base station 105-b provide an updated global model or NN-weights to the UEs 115. Such federated learning may provide relatively fast access to real-time data generated at edge devices for fast training of AI-models, while consuming relatively few radio resources compared to cases where edge devices perform a raw data transfer. Further, federated learning techniques may provide enhanced privacy since raw data are not necessarily needed. However, even using such federated learning techniques, in cases where the machine learning model provides relatively high-dimensional parameters or gradients such information can result in a significant amount of resource consumption (e.g., a 50-layer ResNet may include about 26 million parameters). In order to reduce such resource consumption, compression of gradients or NN-weights may be used for providing distributed gradient updates. Examples of compression techniques are discussed in more detail with reference to FIG. 4.

FIG. 4 illustrates an example of a block-wise gradient vector quantization scheme 400 that supports signaling of gradient vectors for federated learning in a wireless communications system in accordance with aspects of the present disclosure. Such a block-wise gradient vector quantization scheme 400 may be used between edge devices (e.g., UEs 115 as discussed herein) and an edge server (e.g., base stations 105 as discussed herein).

In some cases, a UE (or other edge device) may determine a local stochastic gradient (g) 405 that may be quantized using a block-wise vector quantization technique to generate a quantized stochastic gradient (ĝ) 450 that is reported to a base station (or other edge server). In some cases, quantizers that may be used in such techniques can compress the gradients for transmission via Grassmannian quantizers for normalized vectors. In this example, g 405 is a vector of local stochastic gradients (SGs), and a vectorf 420 is determined where f=g/∥g∥ is the normalized vector of SGs. The vector f may be partitioned into M blocks 425 each with length-L such that f=[v₁^{T}, v₂^{T}, . . . , v_{M}^{T}]^{T}, where the length-L vector vᵢ is referred to as the i-th block gradients. Zero-padding might be used if LM>Dim(f). Further, normalized block gradients may be defined as sᵢ=vᵢ/∥vᵢ∥, and a hinge vector h 430 may be defined as h=[h₁, . . . , h_{M}]^{T}≙[∥vᵥ∥, . . . , ∥v_{M}∥]^{T}.

Quantization may be determined using B_{ρ}-bits to quantize the norm of the local SGs, such that ρ=∥g∥ (as indicated at 410), by a scalar quantizer 415 (C_{ρ}). The scheme may use Bₛ-bits to quantize each normalized block gradient (i.e., sᵢ), by a uniform and even Grassmannian quantizer 440 (Cₛ). A Grassmannian quantizer refers to a quantizer comprising codewords representing unit norm vectors, where an even quantizer codebook is provided such that

C:C=C⁺∪C⁻, with C⁺∩C⁻=∅ and −c∈C⁻, ∀c∈C⁺.

Quantization of h may use Bₕ-bits to quantize each hinge vector by a positive Grassmannian quantizer 435 (Cₕ). The positive quantizer codebook may include codewords within a positive codebook represent only positive-entry vectors.

The quantization may provide a payload size that includes a total of, B_{ρ}+MBₛ+Bₕ bits to quantize the vector g. The quantized version of g is

\hat{g}=\hat{ρ}[\hat{f}₁^{T}, . . . , \hat{f}_{M}^{T}]=\hat{ρ}[\hat{h}₁\hat{s}₁^{T}, . . . , \hat{h}_{M}\hat{s}_{M}^{T}]

where \hat{ρ}, ĥᵢ and ŝᵢ are quantized versions of ρ, hᵢ, and sᵢ, respectively that are combined at combining function 445. For a given bit allocation {B_{ρ}, Bₛ, Bₕ} and partitioning scheme {M, L}, codebooks {C_{ρ}, Cₛ, Cₕ} may to be optimized to minimize estimation MSE between g 405 and ĝ 450. In some cases, the design of the scalar quantizer 415 codebook C_{ρ} may be a uniform scaler quantizer; the design of the Grassmannian quantizer 440 codebook Cₛ may be

$${C}_{s} = arg {max}_{{C}_{s}^{+}} {min}_{\hat{s} \neq \hat{s} {}^{′}} {d}_{c} ( \hat{s} , \hat{s} {}^{′} ) ,$$

where d_{c} stands for chordal distance; and the design of the Grassmannian quantizer 435 codebook Cₕ may be based on an estimation algorithm (e.g., a Lloyd algorithm) since h is not isotropic. The bit allocation may be determined by finding {B_{ρ}, Bₛ, Bₕ} and minimizing a distortion upper-bound subject to B_{ρ}+MBₛ+Bₕ=B bits (e.g., assuming Gaussian distributed gradients), where an optimum {B_{ρ}, Bₛ, Bₕ} depends on {M, L}.

A UE (or other edge device) may be configured to report quantized gradients based by the base station (or other edge server). In some cases, a UE can be RRC configured or MAC-CE/DCI indicated to report block-quantized gradients for federated learning, where the configuration/indication comprises one or more partitioning parameters, one or more quantizer codebook selection parameters, one or more bit allocation parameters, or any combinations thereof. In some cases, the partitioning parameters may include one or more of a block-size (i.e., L), a number of blocks (i.e., M), or any combinations thereof. In some cases, the quantizer codebook selection parameters may include one or more of: one or multiple choices of the scalar quantizer codebooks (e.g., choice(s) of C_{ρ}) for quantizing the norm of gradient vector (e.g., ρ=∥g∥); one or multiple choices of the uniform and even Grassmannian quantizer (e.g., choice(s) of Cₛ) for quantizing each normalized block gradient (i.e., sᵢ); one or multiple choices of the positive Grassmannian quantizer (e.g., choice(s) of Cₕ) for quantizing the hinge vector (i.e., h); or any combinations thereof. In some cases, the bit allocation parameters may include one or more of a total number of bits allocated to report the block-quantized gradients (e.g., B=B_{ρ}+MBₛ+Bₕ); one or multiple choices for at least one of the bit allocations (e.g., choices of {B_{ρ}, Bₛ, Bₕ}), or any combinations thereof. In some cases, the configuration/indication may only include choices for one or two elements in {B_{ρ}, Bₛ, Bₕ}.

In some cases, the UE (or other edge device) may be configured with a number of bits that are to be included in a report to the base station (or other edge server) that indicate one or more of UE determined partitioning parameters, UE determined quantizer codebooks, a UE determined bit allocation scheme, or any combinations thereof. The number of bits, in some cases, may be explicitly configured or indicated in the configuration information from the base station, or may be at least partly identified implicitly based on a quantity of the scheduled UL resources for reporting the quantized gradients. Further, the orders of the bits within the report payload for different purposes (e.g., UE determined partitioning/codebook/bit-allocation, payloads of the bits quantized by different quantizers) may be RRC configured or predetermined (e.g., according to a standard or specification associated with a radio access technology). The UE may receive the configuration information, or one or more portions of the configuration information, separately for each of a group of one or more rounds of gradient reports. In other cases, the UE may receive the configuration information for an overall training task that spans multiple groups of one or more rounds of gradient reporting.

Based on the configuration information, the UE (or other edge device) may report block-quantized gradients to the base station (or other edge server). The block-quantized gradients may be quantized in a multi-stage manner, as discussed herein, and such quantized gradients reporting may be purely based on the base station configured parameters (e.g., the base station configures only one fixed choice for partitioning/codebooks/bit-allocation), may be based in part on the base station configured parameters (e.g., the UE can choose one from the multiple choices for partitioning/codebooks/bit-allocation), may be based in part on a determination at the UE (e.g., based on an amount of uplink resources available for the reporting) and one or more parameters provided by the base station, or may be purely based on a determination at the UE (e.g., the UE determines all partitioning/codebooks/bit-allocation parameters). The UE may report block-quantized gradients in a report payload based on the configuration information. In some cases, one or more parts can be scheduled within the payload of the report, and payload sizes of different parts within the report may be determined at the UE. In some cases, the partitioning/codebooks/bit-allocation determination (if allowed) may be based on base station configuration or predefined values. A quantized value of the gradient vector's norm (e.g., \hat{ρ}) may be based on the bit-allocation for the scalar quantizer quantizing the norm of gradient vector (e.g., B_{ρ}), where the value of B_{ρ} may be determined by one of the options as discussed herein. Quantized values of the normalized block gradients (e.g., ŝᵢ) may be based on the bit-allocation for the uniform and even Grassmannian quantizer (e.g., Bₛ), where the value of Bₛ may be determined by one of the options as discussed herein. Quantized values of the hinge vector (e.g., ĥ) may be based on the bit-allocation for the positive Grassmannian quantizer (e.g., Bₕ), where the value of Bₕ can be determined by one of the options as discussed herein.

In some cases, the UE may receive an uplink grant that provides resources for the reporting of block-quantized gradient vectors. In some cases, the UL resource for such block-quantized gradients may be scheduled as uplink control information (UCI) in a physical uplink control channel (PUCCH) transmission (e.g., UCI-in-PUCCH), UCI in a physical uplink shared channel (PUSCH) transmission (e.g., UCI-in-PUSCH), as information in a MAC-CE or RRC signaling, one or more other upper layer messages or application layer messages, or any combinations thereof. In some cases, a block or block-group specific report may include the quantized values of one or a set of N block normalized gradient vectors (e.g., ŝᵢ or {ŝᵢ, . . . , ŝ_{i+N}}) that can be reported in one configured-grant (CG) PUSCH, and the quantized values of another one or another set of N block normalized gradient vectors (e.g., ŝ_{j,j≠i} or {ŝⱼ, . . . , ŝ_{j+N}}, where {ŝⱼ, . . . , ŝ_{j+N}}∩{ŝᵢ, . . . , ŝ_{i+N}}=∅) can be reported in another CG PUSCH. In some cases, associations between the block or block-group and the CG PUSCHs can be base station configured and indicated, predefined, or reported by the UE (e.g., if the partitioning is determined by the UE, the UE may report such association based on a number of preconfigured CG-PUSCHs). In some cases, reports of determined partitioning/codebooks/bit-allocation can be done for each round of the training procedure, or for a number of rounds of the training procedure, or once for the overall training task. In some cases, other payloads associated with the rounds of the training procedures are determined based on the determined parameters in such reports.

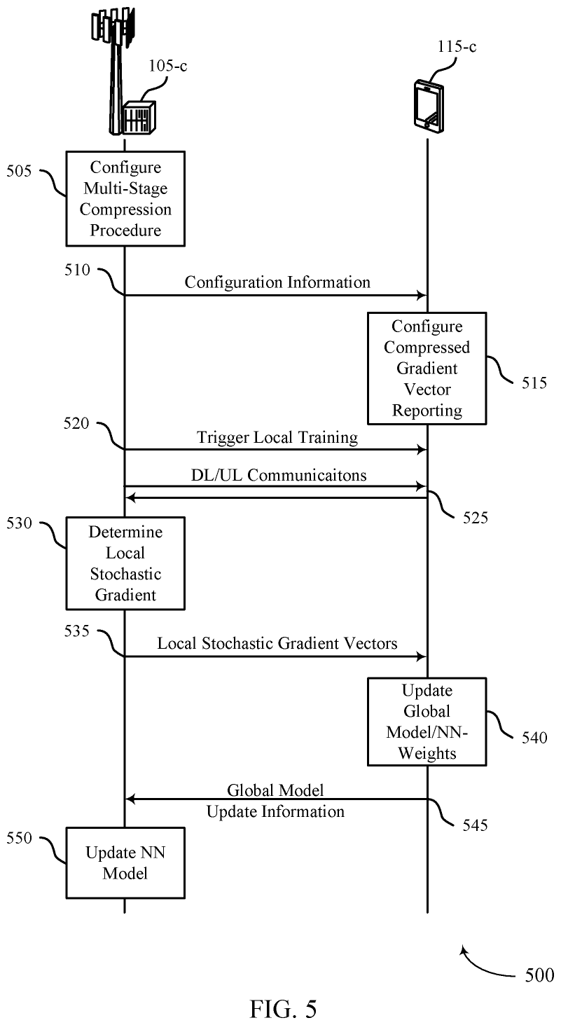

FIG. 5 illustrates an example of a process flow 500 that supports signaling of gradient vectors for federated learning in a wireless communications system in accordance with aspects of the present disclosure. In some examples, process flow 500 may implement aspects of wireless communications system 100-300. The process flow 500 may include base station 105-c and UE 115-c, which may be examples of corresponding devices as described herein. Alternative examples of the following may be implemented, where some steps are performed in a different order than described or are not performed at all. In some cases, steps may include additional features not mentioned below, or further steps may be added.

In some cases, at 505, base station 105-c may configure a multi-stage compression procedure associated with a federated learning process. In some cases, the multi-stage compression configuration may provide configuration for reporting block-quantized gradients as discussed herein (e.g., one or more parameters for partitioning/codebooks/bit-allocation). At 510, the base station 105-c may transmit configuration information to the UE 115-c that configures the multi-stage compression procedure and, in some cases, may configure one or more other aspects for reporting (e.g., one or more CG-PUSCH allocations).

At 515, the UE 115-c may configure UE one or more components for compressed gradient vector reporting based on the configuration information provided by the base station 105-c. In some cases, the configuration information may be provided in RRC signaling, in a MAC-CE, in DCI, in upper layer or application layer signaling, or any combinations thereof. At 520, the base station may trigger local training (e.g., in DCI that indicates a training procedure, or a training round is to be initiated). At 525, UE 115-c and the base station 105-c may perform uplink and downlink communications that may be used for federated learning.

At 530, based on one or more measurements associated with the federated learning procedure, the UE 115-c generate a local dataset and determine a local stochastic gradient. In some cases, the UE 115-c may determine a set of compressed gradient vectors for reporting the local stochastic gradient, in accordance with techniques as discussed herein. At 535, the UE 115-c may transmit the local stochastic gradient vectors to the base station 105-c.

At 540, the base station 105-c may update the global model or NN-weights in accordance with a federated learning procedure. At 545, the base station 105-c may transmit global model update information to the UE 115-c. At 550, the UE 115-c may update the NN model based on the update information from the base station 105-c. The UE 115-c and base station 105-c may transmit and receive communications using the NN model (e.g., using an end-to-end autoencoder) based on the updated model. Such techniques may allow for efficient configuration and reporting of local stochastic gradients through compressed gradient vectors, which may provide information for updated machine learning models and more efficient and reliable communications between the UE 115-c and the base station 105-c.

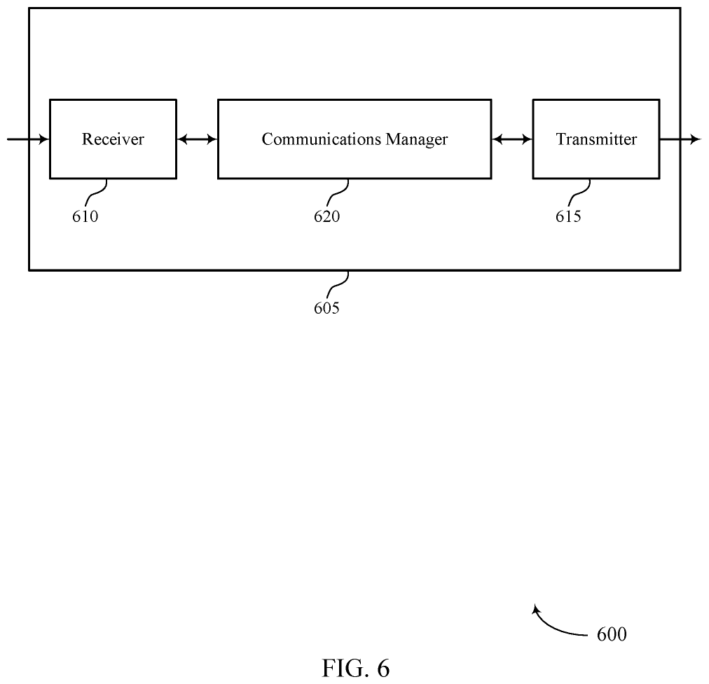

FIG. 6 shows a block diagram 600 of a device 605 that supports signaling of gradient vectors for federated learning in a wireless communications system in accordance with aspects of the present disclosure. The device 605 may be an example of aspects of a UE 115 as described herein. The device 605 may include a receiver 610, a transmitter 615, and a communications manager 620. The device 605 may also include a processor. Each of these components may be in communication with one another (e.g., via one or more buses).

The receiver 610 may provide a means for receiving information such as packets, user data, control information, or any combination thereof associated with various information channels (e.g., control channels, data channels, information channels related to signaling of gradient vectors for federated learning in a wireless communications system). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to signaling of gradient vectors for federated learning in a wireless communications system). In some examples, the transmitter 615 may be co-located with a receiver 610 in a transceiver module. The transmitter 615 may utilize a single antenna or a set of multiple antennas.

The communications manager 620, the receiver 610, the transmitter 615, or various combinations thereof or various components thereof may be examples of means for performing various aspects of signaling of gradient vectors for federated learning in a wireless communications system as described herein. For example, the communications manager 620, the receiver 610, the transmitter 615, or various combinations or components thereof may support a method for performing one or more of the functions described herein.

In some examples, the communications manager 620, the receiver 610, the transmitter 615, or various combinations or components thereof may be implemented in hardware (e.g., in communications management circuitry). The hardware may include a processor, a digital signal processor (DSP), an application-specific integrated circuit (ASIC), a field-programmable gate array (FPGA) or other programmable logic device, a discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally or alternatively, in some examples, the communications manager 620, the receiver 610, the transmitter 615, or various combinations or components thereof may be implemented in code (e.g., as communications management software or firmware) executed by a processor. If implemented in code executed by a processor, the functions of the communications manager 620, the receiver 610, the transmitter 615, or various combinations or components thereof may be performed by a general-purpose processor, a DSP, a central processing unit (CPU), an ASIC, an FPGA, or any combination of these or other programmable logic devices (e.g., configured as or otherwise supporting a means for performing the functions described in the present disclosure).

In some examples, the communications manager 620 may be configured to perform various operations (e.g., receiving, monitoring, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to receive information, transmit information, or perform various other operations as described herein.

The communications manager 620 may support wireless communication at a UE in accordance with examples as disclosed herein. For example, the communications manager 620 may be configured as or otherwise support a means for receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The communications manager 620 may be configured as or otherwise support a means for identifying each compressed gradient vector of the set of multiple compressed gradient vectors based on the machine learning algorithm at the UE and the configuration information. The communications manager 620 may be configured as or otherwise support a means for transmitting each compressed gradient vector of the set of multiple compressed gradient vectors to the base station based on the configuration information.

By including or configuring the communications manager 620 in accordance with examples as described herein, the device 605 (e.g., a processor controlling or otherwise coupled to the receiver 610, the transmitter 615, the communications manager 620, or a combination thereof) may support techniques for efficient configuration and reporting of local stochastic gradients through block-wise compressed gradient vectors, which may provide information for updated machine learning models and more efficient and reliable communications.

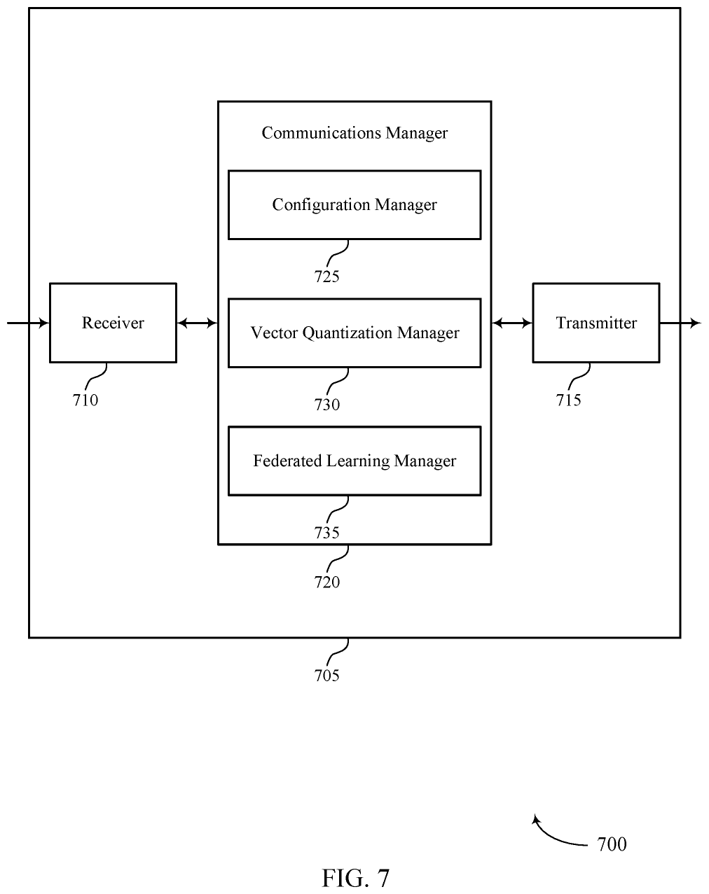

FIG. 7 shows a block diagram 700 of a device 705 that supports signaling of gradient vectors for federated learning in a wireless communications system in accordance with aspects of the present disclosure. The device 705 may be an example of aspects of a device 605 or a UE 115 as described herein. The device 705 may include a receiver 710, a transmitter 715, and a communications manager 720. The device 705 may also include a processor. Each of these components may be in communication with one another (e.g., via one or more buses).

The receiver 710 may provide a means for receiving information such as packets, user data, control information, or any combination thereof associated with various information channels (e.g., control channels, data channels, information channels related to signaling of gradient vectors for federated learning in a wireless communications system). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to signaling of gradient vectors for federated learning in a wireless communications system). In some examples, the transmitter 715 may be co-located with a receiver 710 in a transceiver module. The transmitter 715 may utilize a single antenna or a set of multiple antennas.

The device 705, or various components thereof, may be an example of means for performing various aspects of signaling of gradient vectors for federated learning in a wireless communications system as described herein. For example, the communications manager 720 may include a configuration manager 725, a vector quantization manager 730, a federated learning manager 735, or any combination thereof. The communications manager 720 may be an example of aspects of a communications manager 620 as described herein. In some examples, the communications manager 720, or various components thereof, may be configured to perform various operations (e.g., receiving, monitoring, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to receive information, transmit information, or perform various other operations as described herein.

The communications manager 720 may support wireless communication at a UE in accordance with examples as disclosed herein. The configuration manager 725 may be configured as or otherwise support a means for receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The vector quantization manager 730 may be configured as or otherwise support a means for identifying each compressed gradient vector of the set of multiple compressed gradient vectors based on the machine learning algorithm at the UE and the configuration information. The federated learning manager 735 may be configured as or otherwise support a means for transmitting each compressed gradient vector of the set of multiple compressed gradient vectors to the base station based on the configuration information.

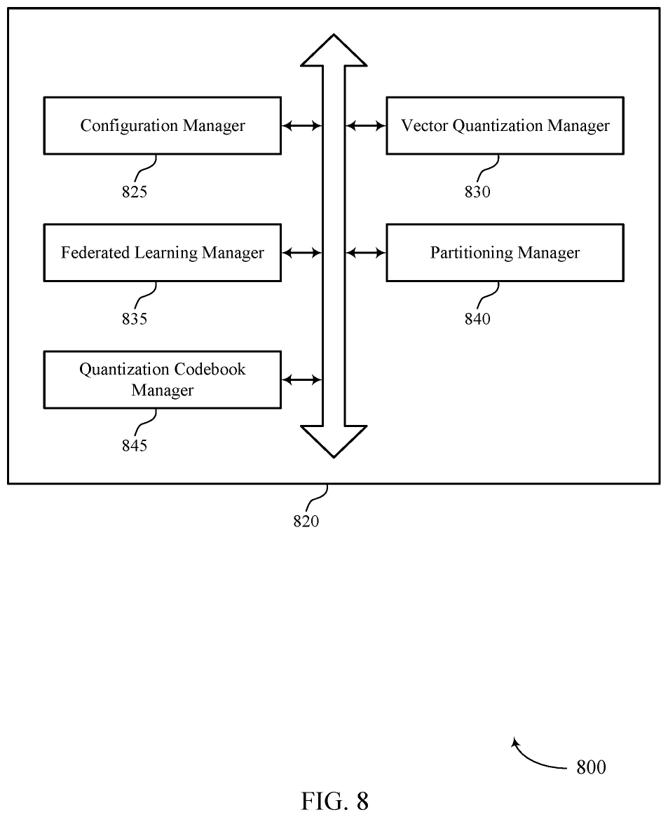

FIG. 8 shows a block diagram 800 of a communications manager 820 that supports signaling of gradient vectors for federated learning in a wireless communications system in accordance with aspects of the present disclosure. The communications manager 820 may be an example of aspects of a communications manager 620, a communications manager 720, or both, as described herein. The communications manager 820, or various components thereof, may be an example of means for performing various aspects of signaling of gradient vectors for federated learning in a wireless communications system as described herein. For example, the communications manager 820 may include a configuration manager 825, a vector quantization manager 830, a federated learning manager 835, a partitioning manager 840, a quantization codebook manager 845, or any combination thereof. Each of these components may communicate, directly or indirectly, with one another (e.g., via one or more buses).

The communications manager 820 may support wireless communication at a UE in accordance with examples as disclosed herein. The configuration manager 825 may be configured as or otherwise support a means for receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The vector quantization manager 830 may be configured as or otherwise support a means for identifying each compressed gradient vector of the set of multiple compressed gradient vectors based on the machine learning algorithm at the UE and the configuration information. The federated learning manager 835 may be configured as or otherwise support a means for transmitting each compressed gradient vector of the set of multiple compressed gradient vectors to the base station based on the configuration information.

In some examples, to support receiving the configuration information, the partitioning manager 840 may be configured as or otherwise support a means for receiving one or more partitioning parameters associated with the local stochastic gradient vector. In some examples, to support receiving the configuration information, the quantization codebook manager 845 may be configured as or otherwise support a means for receiving a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof. In some examples, to support receiving the configuration information, the configuration manager 825 may be configured as or otherwise support a means for receiving one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof.

In some examples, the one or more partitioning parameters indicate a number of blocks of a stochastic gradient that are to be included in the local stochastic gradient vector, a vector length of each block of the number of blocks, or any combinations thereof. In some examples, the set of multiple quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

In some examples, to support receiving the configuration information, the configuration manager 825 may be configured as or otherwise support a means for receiving one or more configuration parameters in radio resource control signaling, in a medium access control (MAC) control element, in downlink control information, in one or more higher layer or application layer communications, or any combinations thereof.

In some examples, the partitioning manager 840 may be configured as or otherwise support a means for selecting, based on the configuration information and the local stochastic gradient vector, a first partitioning parameter of the one or more partitioning parameters, one or more quantization codebooks of the set of multiple quantization codebooks, and a first bit allocation scheme parameter of the one or more bit allocation scheme parameters. In some examples, the partitioning manager 840 may be configured as or otherwise support a means for transmitting, to the base station, an indication of the selected first partitioning parameter, the one or more quantization codebooks, and the first bit allocation scheme parameter using a set of bits that is configured by the configuration information.

In some examples, the set of bits is explicitly indicated by the base station or identified based on an uplink resource for reporting the set of multiple compressed gradient vectors, and where an order of bits within a payload that provides the set of multiple compressed gradient vectors is indicated in the configuration information or is predefined at the UE.

In some examples, the machine learning algorithm provides a set of multiple rounds of compressed gradient vector reporting, and where the configuration information is provided separately for each of the plurality or rounds, or the configuration information is applied to each of the set of multiple rounds.

In some examples, the set of multiple compressed gradient vectors is determined based on a partitioning parameter for the local stochastic gradient vector, one or more quantization codebooks associated with each of the set of multiple compressed gradient vectors, and a payload format for reporting the set of multiple compressed gradient vectors. In some examples, where the partitioning parameter, the one or more quantization codebooks, and the payload format are provided with the configuration information, are selected from a set of available parameters, codebooks, and payload formats that are provided by the base station, or are determined entirely or partly by the UE.

In some examples, the configuration information further indicates a format for a block-quantized gradient report that includes a set of multiple parts for reporting the set of multiple compressed gradient vectors, and a quantity of bits in each of the set of multiple parts.

In some examples, at least one of the sets of multiple parts has a different quantity of bits than one or more other of the set of multiple parts, and where the quantity of bits of each of the set of multiple parts is provided by the configuration information or is predefined at the UE.

In some examples, the block-quantized gradient report includes a first part that indicates a quantized value of a norm of the local stochastic gradient vector that is based on a first bit allocation for an associated scalar quantizer, a second part that indicates quantized values of a set of multiple normalized block gradients of the local stochastic gradient vector that are based on a second bit allocation for a uniform and even Grassmannian quantizer, and a third part that indicates quantized values of a hinge vector associated with the set of multiple normalized block gradients that are based on a third bit allocation for a positive Grassmannian quantizer.

In some examples, the federated learning manager 835 may be configured as or otherwise support a means for receiving, from the base station, an indication of one or more uplink resources for transmission of each of the set of multiple compressed gradient vectors, where the indication is provided in one or more of uplink control information, a medium access control (MAC) control element, in radio resource control signaling, in one or more upper layer messages, or any combinations thereof, and where the set of multiple compressed gradient vectors are transmitted using one or more different uplink resources provided in one or more different uplink grants.

In some examples, the one or more different uplink grants include a set of multiple configured uplink grants for uplink shared channel transmissions, and where different compressed gradient vectors of the set of multiple compressed gradient vectors are transmitted using different configured uplink grants of the set of multiple configured uplink grants, and where. In some examples, the set of multiple configured uplink grants are each associated with different compressed gradient vectors based on an indication provided in the configuration information, a predefined association at the UE, or based on a determination made at the UE and reported to the base station.

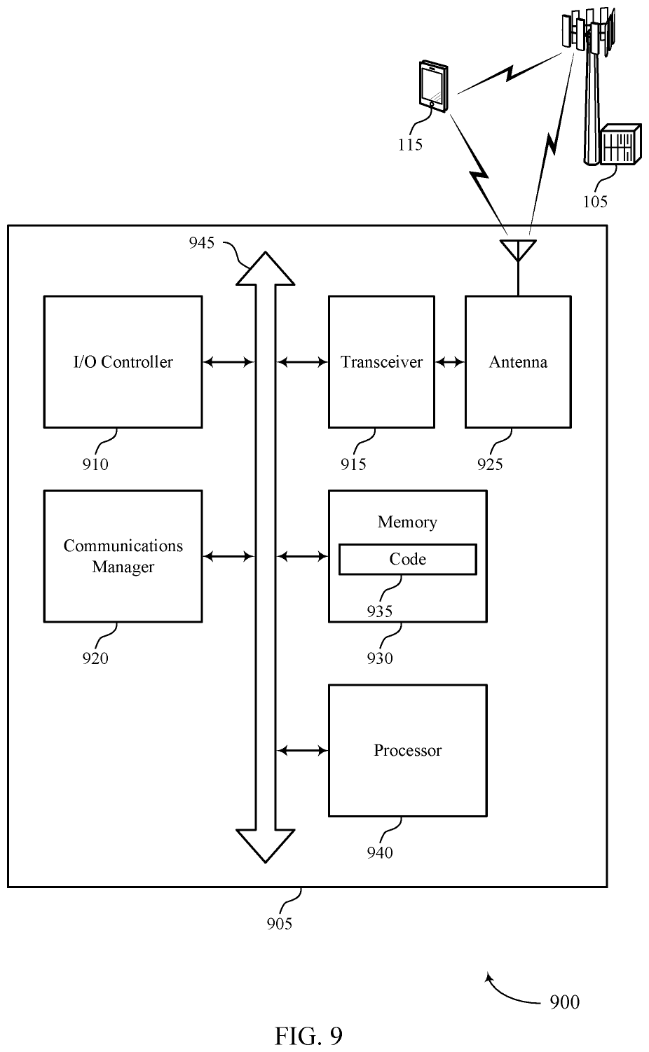

FIG. 9 shows a diagram of a system 900 including a device 905 that supports signaling of gradient vectors for federated learning in a wireless communications system in accordance with aspects of the present disclosure. The device 905 may be an example of or include the components of a device 605, a device 705, or a UE 115 as described herein. The device 905 may communicate wirelessly with one or more base stations 105, UEs 115, or any combination thereof. The device 905 may include components for bi-directional voice and data communications including components for transmitting and receiving communications, such as a communications manager 920, an input/output (I/O) controller 910, a transceiver 915, an antenna 925, a memory 930, code 935, and a processor 940. These components may be in electronic communication or otherwise coupled (e.g., operatively, communicatively, functionally, electronically, electrically) via one or more buses (e.g., a bus 945).

The I/O controller 910 may manage input and output signals for the device 905. The I/O controller 910 may also manage peripherals not integrated into the device 905. In some cases, the I/O controller 910 may represent a physical connection or port to an external peripheral. In some cases, the I/O controller 910 may utilize an operating system such as iOS®, ANDROID®, MS-DOS®, MS-WINDOWS®, OS/2®, UNIX®, LINUX®, or another known operating system. Additionally or alternatively, the I/O controller 910 may represent or interact with a modem, a keyboard, a mouse, a touchscreen, or a similar device. In some cases, the I/O controller 910 may be implemented as part of a processor, such as the processor 940. In some cases, a user may interact with the device 905 via the I/O controller 910 or via hardware components controlled by the I/O controller 910.

In some cases, the device 905 may include a single antenna 925. However, in some other cases, the device 905 may have more than one antenna 925, which may be capable of concurrently transmitting or receiving multiple wireless transmissions. The transceiver 915 may communicate bi-directionally, via the one or more antennas 925, wired, or wireless links as described herein. For example, the transceiver 915 may represent a wireless transceiver and may communicate bi-directionally with another wireless transceiver. The transceiver 915 may also include a modem to modulate the packets, to provide the modulated packets to one or more antennas 925 for transmission, and to demodulate packets received from the one or more antennas 925. The transceiver 915, or the transceiver 915 and one or more antennas 925, may be an example of a transmitter 615, a transmitter 715, a receiver 610, a receiver 710, or any combination thereof or component thereof, as described herein.

The memory 930 may include random access memory (RAM) and read-only memory (ROM). The memory 930 may store computer-readable, computer-executable code 935 including instructions that, when executed by the processor 940, cause the device 905 to perform various functions described herein. The code 935 may be stored in a non-transitory computer-readable medium such as system memory or another type of memory. In some cases, the code 935 may not be directly executable by the processor 940 but may cause a computer (e.g., when compiled and executed) to perform functions described herein. In some cases, the memory 930 may contain, among other things, a basic I/O system (BIOS) which may control basic hardware or software operation such as the interaction with peripheral components or devices.

The processor 940 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 940 may be configured to operate a memory array using a memory controller. In some other cases, a memory controller may be integrated into the processor 940. The processor 940 may be configured to execute computer-readable instructions stored in a memory (e.g., the memory 930) to cause the device 905 to perform various functions (e.g., functions or tasks supporting signaling of gradient vectors for federated learning in a wireless communications system). For example, the device 905 or a component of the device 905 may include a processor 940 and memory 930 coupled to the processor 940, the processor 940 and memory 930 configured to perform various functions described herein.

The communications manager 920 may support wireless communication at a UE in accordance with examples as disclosed herein. For example, the communications manager 920 may be configured as or otherwise support a means for receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The communications manager 920 may be configured as or otherwise support a means for identifying each compressed gradient vector of the set of multiple compressed gradient vectors based on the machine learning algorithm at the UE and the configuration information. The communications manager 920 may be configured as or otherwise support a means for transmitting each compressed gradient vector of the set of multiple compressed gradient vectors to the base station based on the configuration information.

By including or configuring the communications manager 920 in accordance with examples as described herein, the device 905 may support techniques for efficient configuration and reporting of local stochastic gradients through block-wise compressed gradient vectors, which may provide information for updated machine learning models and more efficient and reliable communications. Efficient updating of machine learning models may provide improved communication reliability, reduced latency, improved user experience related to reduced processing, reduced power consumption, more efficient utilization of communication resources, improved coordination between devices, longer battery life, improved utilization of processing capability, and other advantages.

In some examples, the communications manager 920 may be configured to perform various operations (e.g., receiving, monitoring, transmitting) using or otherwise in cooperation with the transceiver 915, the one or more antennas 925, or any combination thereof. Although the communications manager 920 is illustrated as a separate component, in some examples, one or more functions described with reference to the communications manager 920 may be supported by or performed by the processor 940, the memory 930, the code 935, or any combination thereof. For example, the code 935 may include instructions executable by the processor 940 to cause the device 905 to perform various aspects of signaling of gradient vectors for federated learning in a wireless communications system as described herein, or the processor 940 and the memory 930 may be otherwise configured to perform or support such operations.

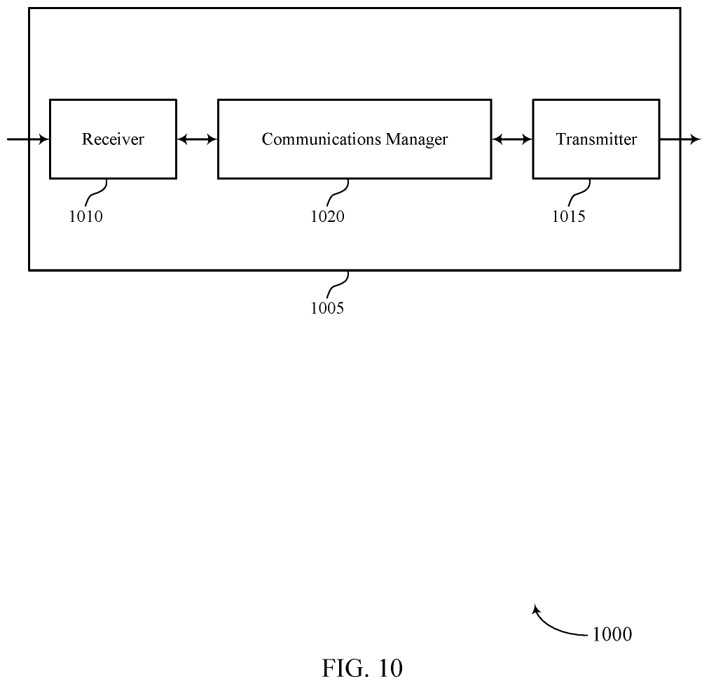

FIG. 10 shows a block diagram 1000 of a device 1005 that supports signaling of gradient vectors for federated learning in a wireless communications system in accordance with aspects of the present disclosure. The device 1005 may be an example of aspects of a base station 105 as described herein. The device 1005 may include a receiver 1010, a transmitter 1015, and a communications manager 1020. The device 1005 may also include a processor. Each of these components may be in communication with one another (e.g., via one or more buses).

The receiver 1010 may provide a means for receiving information such as packets, user data, control information, or any combination thereof associated with various information channels (e.g., control channels, data channels, information channels related to signaling of gradient vectors for federated learning in a wireless communications system). Information may be passed on to other components of the device 1005. The receiver 1010 may utilize a single antenna or a set of multiple antennas.

The transmitter 1015 may provide a means for transmitting signals generated by other components of the device 1005. For example, the transmitter 1015 may transmit information such as packets, user data, control information, or any combination thereof associated with various information channels (e.g., control channels, data channels, information channels related to signaling of gradient vectors for federated learning in a wireless communications system). In some examples, the transmitter 1015 may be co-located with a receiver 1010 in a transceiver module. The transmitter 1015 may utilize a single antenna or a set of multiple antennas.

The communications manager 1020, the receiver 1010, the transmitter 1015, or various combinations thereof or various components thereof may be examples of means for performing various aspects of signaling of gradient vectors for federated learning in a wireless communications system as described herein. For example, the communications manager 1020, the receiver 1010, the transmitter 1015, or various combinations or components thereof may support a method for performing one or more of the functions described herein.

In some examples, the communications manager 1020, the receiver 1010, the transmitter 1015, or various combinations or components thereof may be implemented in hardware (e.g., in communications management circuitry). The hardware may include a processor, a DSP, an ASIC, an FPGA or other programmable logic device, a discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally or alternatively, in some examples, the communications manager 1020, the receiver 1010, the transmitter 1015, or various combinations or components thereof may be implemented in code (e.g., as communications management software or firmware) executed by a processor. If implemented in code executed by a processor, the functions of the communications manager 1020, the receiver 1010, the transmitter 1015, or various combinations or components thereof may be performed by a general-purpose processor, a DSP, a CPU, an ASIC, an FPGA, or any combination of these or other programmable logic devices (e.g., configured as or otherwise supporting a means for performing the functions described in the present disclosure).

In some examples, the communications manager 1020 may be configured to perform various operations (e.g., receiving, monitoring, transmitting) using or otherwise in cooperation with the receiver 1010, the transmitter 1015, or both. For example, the communications manager 1020 may receive information from the receiver 1010, send information to the transmitter 1015, or be integrated in combination with the receiver 1010, the transmitter 1015, or both to receive information, transmit information, or perform various other operations as described herein.

The communications manager 1020 may support wireless communication at a base station in accordance with examples as disclosed herein. For example, the communications manager 1020 may be configured as or otherwise support a means for transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The communications manager 1020 may be configured as or otherwise support a means for initiating the machine learning algorithm at the set of multiple UEs as part of a federated machine learning procedure. The communications manager 1020 may be configured as or otherwise support a means for receiving, from each of the set of multiple UEs, the set of multiple compressed gradient vectors based on the machine learning algorithm at each UE and the configuration information.

By including or configuring the communications manager 1020 in accordance with examples as described herein, the device 1005 (e.g., a processor controlling or otherwise coupled to the receiver 1010, the transmitter 1015, the communications manager 1020, or a combination thereof) may support techniques for updated machine learning models through federated learning using block-quantized gradient vectors for more efficient and reliable communications.

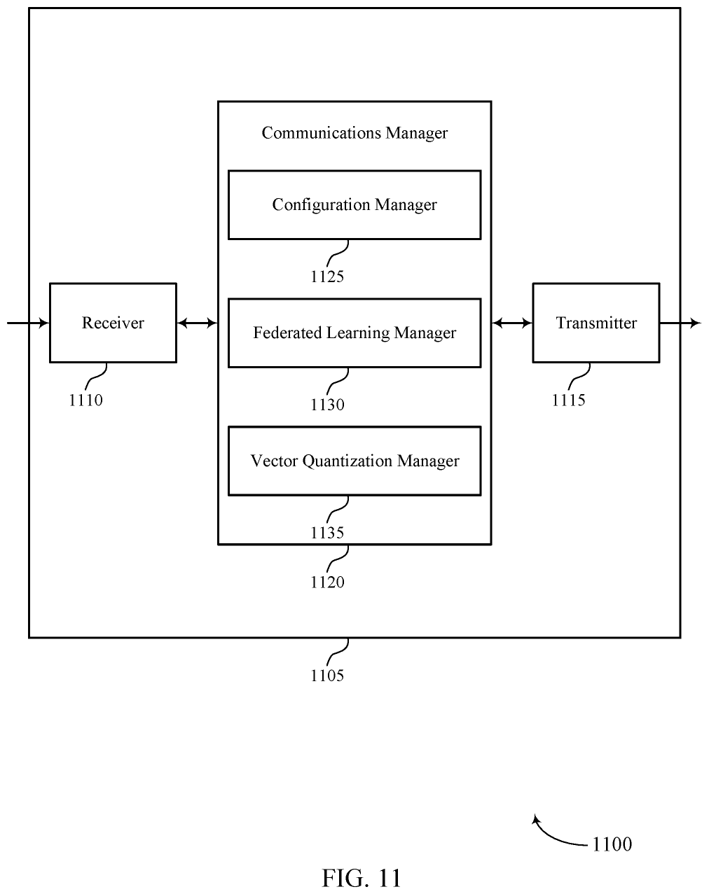

FIG. 11 shows a block diagram 1100 of a device 1105 that supports signaling of gradient vectors for federated learning in a wireless communications system in accordance with aspects of the present disclosure. The device 1105 may be an example of aspects of a device 1005 or a base station 105 as described herein. The device 1105 may include a receiver 1110, a transmitter 1115, and a communications manager 1120. The device 1105 may also include a processor. Each of these components may be in communication with one another (e.g., via one or more buses).

The receiver 1110 may provide a means for receiving information such as packets, user data, control information, or any combination thereof associated with various information channels (e.g., control channels, data channels, information channels related to signaling of gradient vectors for federated learning in a wireless communications system). Information may be passed on to other components of the device 1105. The receiver 1110 may utilize a single antenna or a set of multiple antennas.

The transmitter 1115 may provide a means for transmitting signals generated by other components of the device 1105. For example, the transmitter 1115 may transmit information such as packets, user data, control information, or any combination thereof associated with various information channels (e.g., control channels, data channels, information channels related to signaling of gradient vectors for federated learning in a wireless communications system). In some examples, the transmitter 1115 may be co-located with a receiver 1110 in a transceiver module. The transmitter 1115 may utilize a single antenna or a set of multiple antennas.

The device 1105, or various components thereof, may be an example of means for performing various aspects of signaling of gradient vectors for federated learning in a wireless communications system as described herein. For example, the communications manager 1120 may include a configuration manager 1125, a federated learning manager 1130, a vector quantization manager 1135, or any combination thereof. The communications manager 1120 may be an example of aspects of a communications manager 1020 as described herein. In some examples, the communications manager 1120, or various components thereof, may be configured to perform various operations (e.g., receiving, monitoring, transmitting) using or otherwise in cooperation with the receiver 1110, the transmitter 1115, or both. For example, the communications manager 1120 may receive information from the receiver 1110, send information to the transmitter 1115, or be integrated in combination with the receiver 1110, the transmitter 1115, or both to receive information, transmit information, or perform various other operations as described herein.

The communications manager 1120 may support wireless communication at a base station in accordance with examples as disclosed herein. The configuration manager 1125 may be configured as or otherwise support a means for transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The federated learning manager 1130 may be configured as or otherwise support a means for initiating the machine learning algorithm at the set of multiple UEs as part of a federated machine learning procedure. The vector quantization manager 1135 may be configured as or otherwise support a means for receiving, from each of the set of multiple UEs, the set of multiple compressed gradient vectors based on the machine learning algorithm at each UE and the configuration information.

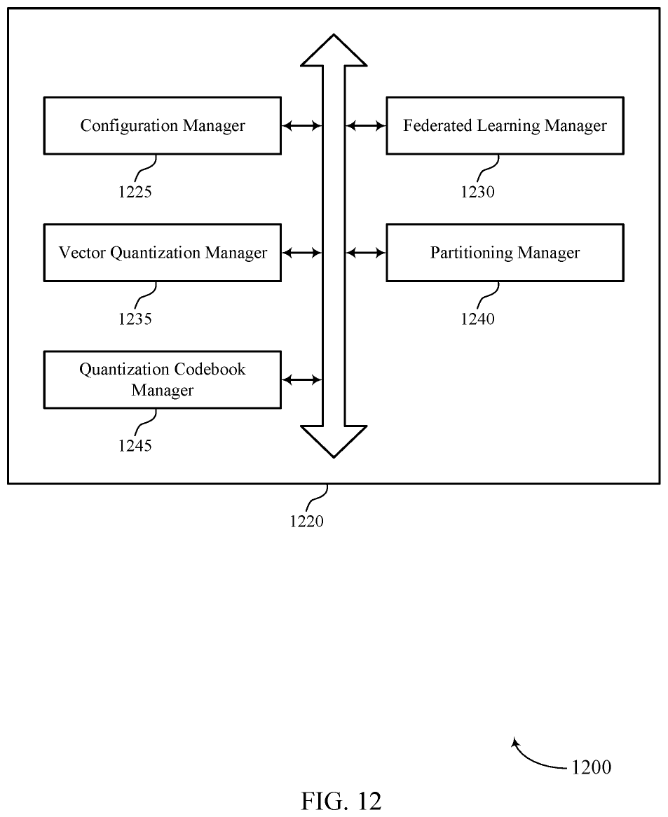

FIG. 12 shows a block diagram 1200 of a communications manager 1220 that supports signaling of gradient vectors for federated learning in a wireless communications system in accordance with aspects of the present disclosure. The communications manager 1220 may be an example of aspects of a communications manager 1020, a communications manager 1120, or both, as described herein. The communications manager 1220, or various components thereof, may be an example of means for performing various aspects of signaling of gradient vectors for federated learning in a wireless communications system as described herein. For example, the communications manager 1220 may include a configuration manager 1225, a federated learning manager 1230, a vector quantization manager 1235, a partitioning manager 1240, a quantization codebook manager 1245, or any combination thereof. Each of these components may communicate, directly or indirectly, with one another (e.g., via one or more buses).

The communications manager 1220 may support wireless communication at a base station in accordance with examples as disclosed herein. The configuration manager 1225 may be configured as or otherwise support a means for transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The federated learning manager 1230 may be configured as or otherwise support a means for initiating the machine learning algorithm at the set of multiple UEs as part of a federated machine learning procedure. The vector quantization manager 1235 may be configured as or otherwise support a means for receiving, from each of the set of multiple UEs, the set of multiple compressed gradient vectors based on the machine learning algorithm at each UE and the configuration information.

In some examples, to support transmitting the configuration information, the partitioning manager 1240 may be configured as or otherwise support a means for transmitting one or more partitioning parameters associated with the local stochastic gradient vector. In some examples, to support transmitting the configuration information, the quantization codebook manager 1245 may be configured as or otherwise support a means for transmitting a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof. In some examples, to support transmitting the configuration information, the configuration manager 1225 may be configured as or otherwise support a means for transmitting one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof.

In some examples, the one or more partitioning parameters indicate a number of blocks of a stochastic gradient that are to be included in the local stochastic gradient vector, a vector length of each block of the number of blocks, or any combinations thereof. In some examples, the set of multiple quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

In some examples, the configuration manager 1225 may be configured as or otherwise support a means for configuring the set of multiple UEs to select, based on the configuration information and the associated local stochastic gradient vector, a first partitioning parameter of the one or more partitioning parameters, one or more quantization codebooks of the set of multiple quantization codebooks, and a first bit allocation scheme parameter of the one or more bit allocation scheme parameters. In some examples, the configuration manager 1225 may be configured as or otherwise support a means for configuring the set of multiple UEs to report the selected parameter, codebooks, and allocation scheme parameter, using a set of bits. In some examples, the federated learning manager 1230 may be configured as or otherwise support a means for receiving, from the set of multiple UEs, the set of bits that provide associated indications of the selected first partitioning parameter, the one or more quantization codebooks, and the first bit allocation scheme parameter.

In some examples, the set of multiple compressed gradient vectors are determined based on a partitioning parameter for the local stochastic gradient vector, one or more quantization codebooks associated with each of the set of multiple compressed gradient vectors, and a payload format for reporting the set of multiple compressed gradient vectors. In some examples, where the partitioning parameter, the one or more quantization codebooks, and the payload format are provided with the configuration information, are selected from a set of available parameters, codebooks, and payload formats that are provided by the base station, or are determined entirely or partly by the UE.

In some examples, the configuration information further indicates a format for a block-quantized gradient report that includes a set of multiple parts for reporting the set of multiple compressed gradient vectors, and a quantity of bits in each of the set of multiple parts.

In some examples, at least one of the sets of multiple parts has a different quantity of bits than one or more other of the set of multiple parts, and where the quantity of bits of each of the set of multiple parts is provided by the configuration information or is predefined at the UE.

In some examples, the block-quantized gradient report includes a first part that indicates a quantized value of a norm of the local stochastic gradient vector that is based on a first bit allocation for an associated scalar quantizer, a second part that indicates quantized values of a set of multiple normalized block gradients of the local stochastic gradient vector that are based on a second bit allocation for a uniform and even Grassmannian quantizer, and a third part that indicates quantized values of a hinge vector associated with the set of multiple normalized block gradients that are based on a third bit allocation for a positive Grassmannian quantizer.

In some examples, the federated learning manager 1230 may be configured as or otherwise support a means for transmitting, to each of the set of multiple UEs, an indication of one or more uplink resources for transmission of each of the set of multiple compressed gradient vectors, where the indication is provided in one or more of uplink control information, a medium access control (MAC) control element, in radio resource control signaling, in one or more upper layer messages, or any combinations thereof, and where the set of multiple compressed gradient vectors are transmitted using one or more different uplink resources provided in one or more different uplink grants.

In some examples, the one or more different uplink grants include a set of multiple configured uplink grants for uplink shared channel transmissions, and where different compressed gradient vectors of the set of multiple compressed gradient vectors are transmitted using different configured uplink grants of the set of multiple configured uplink grants, and where. In some examples, the set of multiple configured uplink grants are each associated with different compressed gradient vectors based on an indication provided in the configuration information, a predefined association at the UE, or based on a determination made at the UE and reported to the base station.

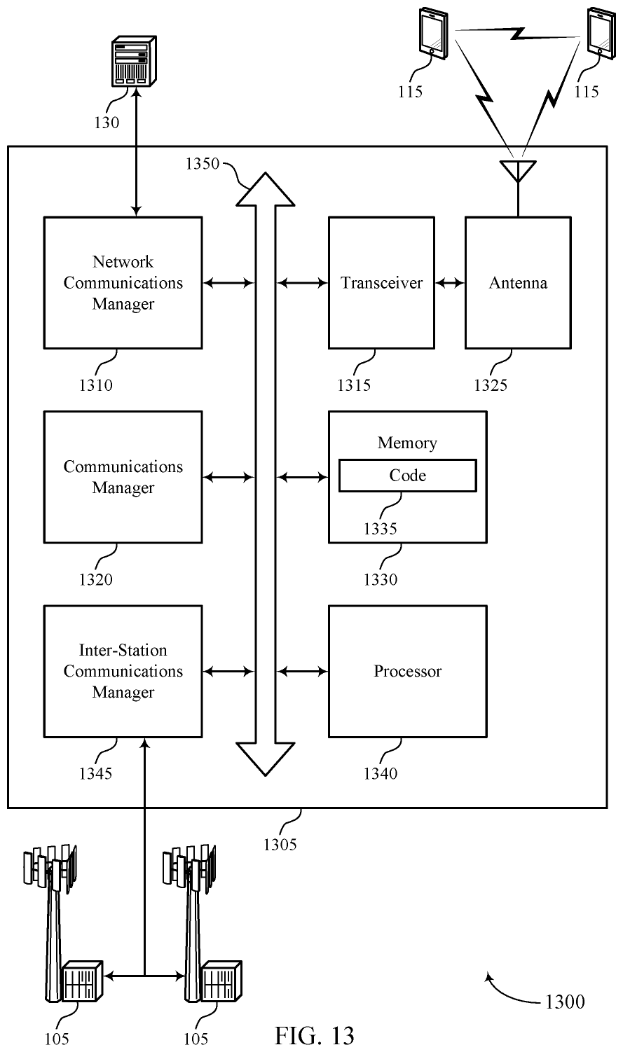

FIG. 13 shows a diagram of a system 1300 including a device 1305 that supports signaling of gradient vectors for federated learning in a wireless communications system in accordance with aspects of the present disclosure. The device 1305 may be an example of or include the components of a device 1005, a device 1105, or a base station 105 as described herein. The device 1305 may communicate wirelessly with one or more base stations 105, UEs 115, or any combination thereof. The device 1305 may include components for bi-directional voice and data communications including components for transmitting and receiving communications, such as a communications manager 1320, a network communications manager 1310, a transceiver 1315, an antenna 1325, a memory 1330, code 1335, a processor 1340, and an inter-station communications manager 1345. These components may be in electronic communication or otherwise coupled (e.g., operatively, communicatively, functionally, electronically, electrically) via one or more buses (e.g., a bus 1350).

The network communications manager 1310 may manage communications with a core network 130 (e.g., via one or more wired backhaul links). For example, the network communications manager 1310 may manage the transfer of data communications for client devices, such as one or more UEs 115.

In some cases, the device 1305 may include a single antenna 1325. However, in some other cases the device 1305 may have more than one antenna 1325, which may be capable of concurrently transmitting or receiving multiple wireless transmissions. The transceiver 1315 may communicate bi-directionally, via the one or more antennas 1325, wired, or wireless links as described herein. For example, the transceiver 1315 may represent a wireless transceiver and may communicate bi-directionally with another wireless transceiver. The transceiver 1315 may also include a modem to modulate the packets, to provide the modulated packets to one or more antennas 1325 for transmission, and to demodulate packets received from the one or more antennas 1325. The transceiver 1315, or the transceiver 1315 and one or more antennas 1325, may be an example of a transmitter 1015, a transmitter 1115, a receiver 1010, a receiver 1110, or any combination thereof or component thereof, as described herein.

The memory 1330 may include RAM and ROM. The memory 1330 may store computer-readable, computer-executable code 1335 including instructions that, when executed by the processor 1340, cause the device 1305 to perform various functions described herein. The code 1335 may be stored in a non-transitory computer-readable medium such as system memory or another type of memory. In some cases, the code 1335 may not be directly executable by the processor 1340 but may cause a computer (e.g., when compiled and executed) to perform functions described herein. In some cases, the memory 1330 may contain, among other things, a BIOS which may control basic hardware or software operation such as the interaction with peripheral components or devices.

The processor 1340 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 1340 may be configured to operate a memory array using a memory controller. In some other cases, a memory controller may be integrated into the processor 1340. The processor 1340 may be configured to execute computer-readable instructions stored in a memory (e.g., the memory 1330) to cause the device 1305 to perform various functions (e.g., functions or tasks supporting signaling of gradient vectors for federated learning in a wireless communications system). For example, the device 1305 or a component of the device 1305 may include a processor 1340 and memory 1330 coupled to the processor 1340, the processor 1340 and memory 1330 configured to perform various functions described herein.

The inter-station communications manager 1345 may manage communications with other base stations 105, and may include a controller or scheduler for controlling communications with UEs 115 in cooperation with other base stations 105. For example, the inter-station communications manager 1345 may coordinate scheduling for transmissions to UEs 115 for various interference mitigation techniques such as beamforming or joint transmission. In some examples, the inter-station communications manager 1345 may provide an X2 interface within an LTE/LTE-A wireless communications network technology to provide communication between base stations 105.

The communications manager 1320 may support wireless communication at a base station in accordance with examples as disclosed herein. For example, the communications manager 1320 may be configured as or otherwise support a means for transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The communications manager 1320 may be configured as or otherwise support a means for initiating the machine learning algorithm at the set of multiple UEs as part of a federated machine learning procedure. The communications manager 1320 may be configured as or otherwise support a means for receiving, from each of the set of multiple UEs, the set of multiple compressed gradient vectors based on the machine learning algorithm at each UE and the configuration information.

By including or configuring the communications manager 1320 in accordance with examples as described herein, the device 1305 may support techniques for updated machine learning models through federated learning using block-quantized gradient vectors for more efficient and reliable communications. Efficient updating of machine learning models may provide improved communication reliability, reduced latency, improved user experience related to reduced processing, reduced power consumption, more efficient utilization of communication resources, improved coordination between devices, longer battery life, improved utilization of processing capability, and other advantages.

In some examples, the communications manager 1320 may be configured to perform various operations (e.g., receiving, monitoring, transmitting) using or otherwise in cooperation with the transceiver 1315, the one or more antennas 1325, or any combination thereof. Although the communications manager 1320 is illustrated as a separate component, in some examples, one or more functions described with reference to the communications manager 1320 may be supported by or performed by the processor 1340, the memory 1330, the code 1335, or any combination thereof. For example, the code 1335 may include instructions executable by the processor 1340 to cause the device 1305 to perform various aspects of signaling of gradient vectors for federated learning in a wireless communications system as described herein, or the processor 1340 and the memory 1330 may be otherwise configured to perform or support such operations.

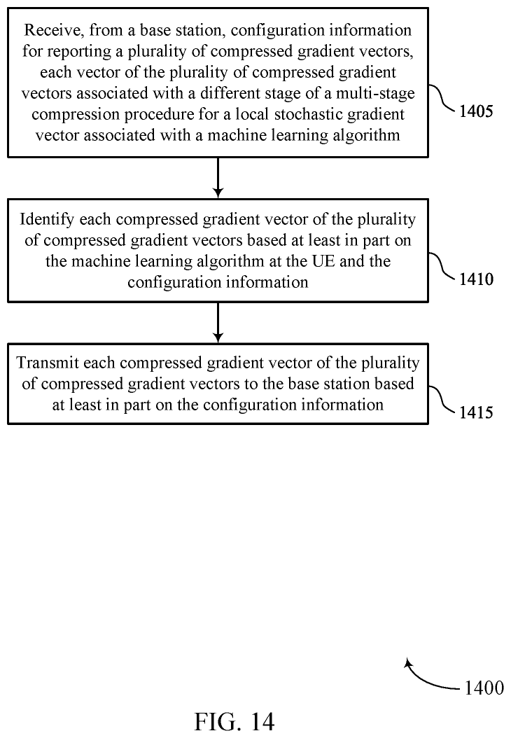

FIG. 14 shows a flowchart illustrating a method 1400 that supports signaling of gradient vectors for federated learning in a wireless communications system in accordance with aspects of the present disclosure. The operations of the method 1400 may be implemented by a UE or its components as described herein. For example, the operations of the method 1400 may be performed by a UE 115 as described with reference to FIGS. 1 through 9. In some examples, a UE may execute a set of instructions to control the functional elements of the UE to perform the described functions. Additionally or alternatively, the UE may perform aspects of the described functions using special-purpose hardware.

At 1405, the method may include receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 1405 may be performed in accordance with examples as disclosed herein. In some examples, aspects of the operations of 1405 may be performed by a configuration manager 825 as described with reference to FIG. 8.

At 1410, the method may include identifying each compressed gradient vector of the set of multiple compressed gradient vectors based on the machine learning algorithm at the UE and the configuration information. The operations of 1410 may be performed in accordance with examples as disclosed herein. In some examples, aspects of the operations of 1410 may be performed by a vector quantization manager 830 as described with reference to FIG. 8.

At 1415, the method may include transmitting each compressed gradient vector of the set of multiple compressed gradient vectors to the base station based on the configuration information. The operations of 1415 may be performed in accordance with examples as disclosed herein. In some examples, aspects of the operations of 1415 may be performed by a federated learning manager 835 as described with reference to FIG. 8.

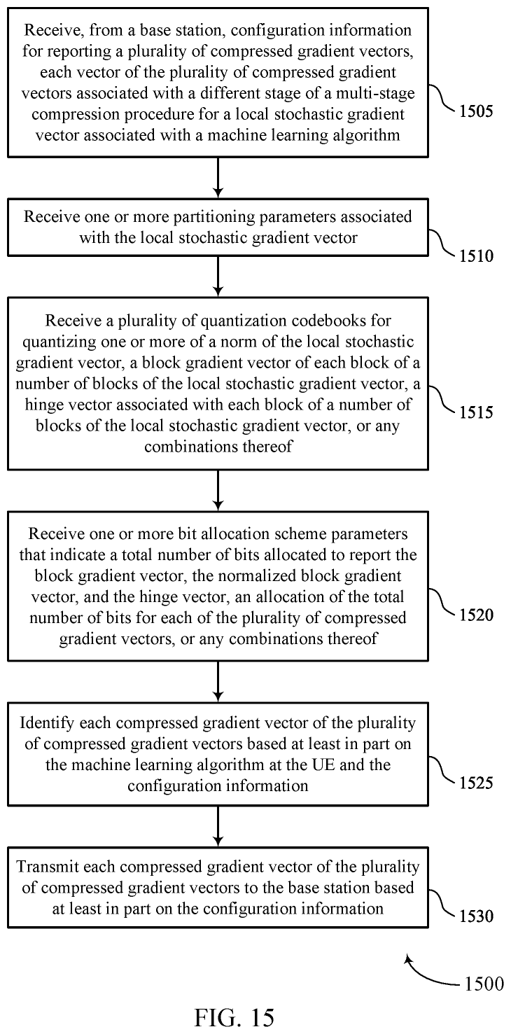

FIG. 15 shows a flowchart illustrating a method 1500 that supports signaling of gradient vectors for federated learning in a wireless communications system in accordance with aspects of the present disclosure. The operations of the method 1500 may be implemented by a UE or its components as described herein. For example, the operations of the method 1500 may be performed by a UE 115 as described with reference to FIGS. 1 through 9. In some examples, a UE may execute a set of instructions to control the functional elements of the UE to perform the described functions. Additionally or alternatively, the UE may perform aspects of the described functions using special-purpose hardware.

At 1505, the method may include receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 1505 may be performed in accordance with examples as disclosed herein. In some examples, aspects of the operations of 1505 may be performed by a configuration manager 825 as described with reference to FIG. 8.

At 1510, the method may include receiving one or more partitioning parameters associated with the local stochastic gradient vector. The operations of 1510 may be performed in accordance with examples as disclosed herein. In some examples, aspects of the operations of 1510 may be performed by a partitioning manager 840 as described with reference to FIG. 8.

At 1515, the method may include receiving a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof. The operations of 1515 may be performed in accordance with examples as disclosed herein. In some examples, aspects of the operations of 1515 may be performed by a quantization codebook manager 845 as described with reference to FIG. 8.

At 1520, the method may include receiving one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof. The operations of 1520 may be performed in accordance with examples as disclosed herein. In some examples, aspects of the operations of 1520 may be performed by a configuration manager 825 as described with reference to FIG. 8.

At 1525, the method may include identifying each compressed gradient vector of the set of multiple compressed gradient vectors based on the machine learning algorithm at the UE and the configuration information. The operations of 1525 may be performed in accordance with examples as disclosed herein. In some examples, aspects of the operations of 1525 may be performed by a vector quantization manager 830 as described with reference to FIG. 8.

At 1530, the method may include transmitting each compressed gradient vector of the set of multiple compressed gradient vectors to the base station based on the configuration information. The operations of 1530 may be performed in accordance with examples as disclosed herein. In some examples, aspects of the operations of 1530 may be performed by a federated learning manager 835 as described with reference to FIG. 8.

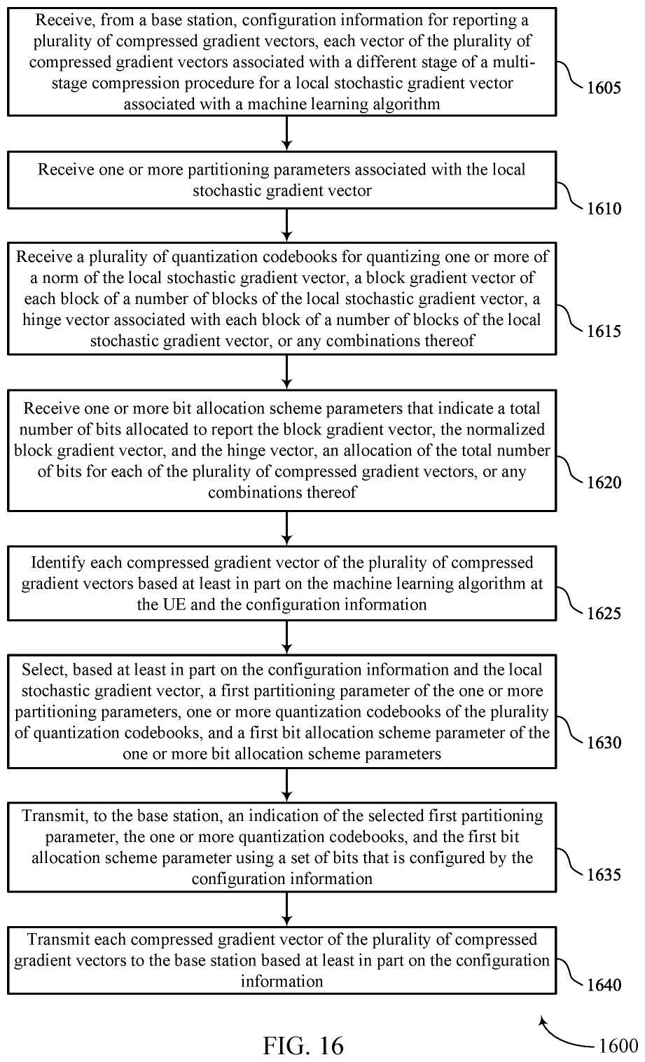

FIG. 16 shows a flowchart illustrating a method 1600 that supports signaling of gradient vectors for federated learning in a wireless communications system in accordance with aspects of the present disclosure. The operations of the method 1600 may be implemented by a UE or its components as described herein. For example, the operations of the method 1600 may be performed by a UE 115 as described with reference to FIGS. 1 through 9. In some examples, a UE may execute a set of instructions to control the functional elements of the UE to perform the described functions. Additionally or alternatively, the UE may perform aspects of the described functions using special-purpose hardware.

At 1605, the method may include receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 1605 may be performed in accordance with examples as disclosed herein. In some examples, aspects of the operations of 1605 may be performed by a configuration manager 825 as described with reference to FIG. 8.

At 1610, the method may include receiving one or more partitioning parameters associated with the local stochastic gradient vector. The operations of 1610 may be performed in accordance with examples as disclosed herein. In some examples, aspects of the operations of 1610 may be performed by a partitioning manager 840 as described with reference to FIG. 8.

At 1615, the method may include receiving a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof. The operations of 1615 may be performed in accordance with examples as disclosed herein. In some examples, aspects of the operations of 1615 may be performed by a quantization codebook manager 845 as described with reference to FIG. 8.

At 1620, the method may include receiving one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof. The operations of 1620 may be performed in accordance with examples as disclosed herein. In some examples, aspects of the operations of 1620 may be performed by a configuration manager 825 as described with reference to FIG. 8.

At 1625, the method may include identifying each compressed gradient vector of the set of multiple compressed gradient vectors based on the machine learning algorithm at the UE and the configuration information. The operations of 1625 may be performed in accordance with examples as disclosed herein. In some examples, aspects of the operations of 1625 may be performed by a vector quantization manager 830 as described with reference to FIG. 8.

At 1630, the method may include selecting, based on the configuration information and the local stochastic gradient vector, a first partitioning parameter of the one or more partitioning parameters, one or more quantization codebooks of the set of multiple quantization codebooks, and a first bit allocation scheme parameter of the one or more bit allocation scheme parameters. The operations of 1630 may be performed in accordance with examples as disclosed herein. In some examples, aspects of the operations of 1630 may be performed by a partitioning manager 840 as described with reference to FIG. 8.

At 1635, the method may include transmitting, to the base station, an indication of the selected first partitioning parameter, the one or more quantization codebooks, and the first bit allocation scheme parameter using a set of bits that is configured by the configuration information. The operations of 1635 may be performed in accordance with examples as disclosed herein. In some examples, aspects of the operations of 1635 may be performed by a partitioning manager 840 as described with reference to FIG. 8.

At 1640, the method may include transmitting each compressed gradient vector of the set of multiple compressed gradient vectors to the base station based on the configuration information. The operations of 1640 may be performed in accordance with examples as disclosed herein. In some examples, aspects of the operations of 1640 may be performed by a federated learning manager 835 as described with reference to FIG. 8.

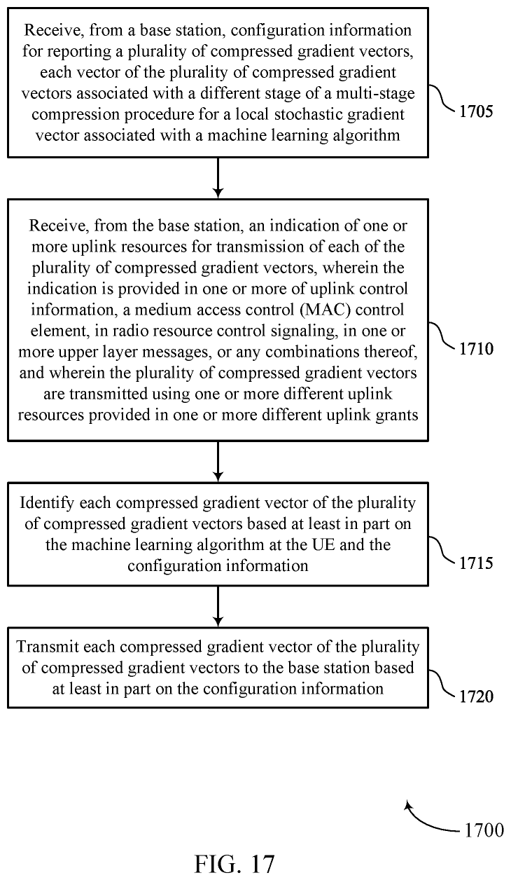

FIG. 17 shows a flowchart illustrating a method 1700 that supports signaling of gradient vectors for federated learning in a wireless communications system in accordance with aspects of the present disclosure. The operations of the method 1700 may be implemented by a UE or its components as described herein. For example, the operations of the method 1700 may be performed by a UE 115 as described with reference to FIGS. 1 through 9. In some examples, a UE may execute a set of instructions to control the functional elements of the UE to perform the described functions. Additionally or alternatively, the UE may perform aspects of the described functions using special-purpose hardware.

At 1705, the method may include receiving, from a base station, configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 1705 may be performed in accordance with examples as disclosed herein. In some examples, aspects of the operations of 1705 may be performed by a configuration manager 825 as described with reference to FIG. 8.

At 1710, the method may include receiving, from the base station, an indication of one or more uplink resources for transmission of each of the set of multiple compressed gradient vectors, where the indication is provided in one or more of uplink control information, a medium access control (MAC) control element, in radio resource control signaling, in one or more upper layer messages, or any combinations thereof, and where the set of multiple compressed gradient vectors are transmitted using one or more different uplink resources provided in one or more different uplink grants. The operations of 1710 may be performed in accordance with examples as disclosed herein. In some examples, aspects of the operations of 1710 may be performed by a federated learning manager 835 as described with reference to FIG. 8.

At 1715, the method may include identifying each compressed gradient vector of the set of multiple compressed gradient vectors based on the machine learning algorithm at the UE and the configuration information. The operations of 1715 may be performed in accordance with examples as disclosed herein. In some examples, aspects of the operations of 1715 may be performed by a vector quantization manager 830 as described with reference to FIG. 8.

At 1720, the method may include transmitting each compressed gradient vector of the set of multiple compressed gradient vectors to the base station based on the configuration information. The operations of 1720 may be performed in accordance with examples as disclosed herein. In some examples, aspects of the operations of 1720 may be performed by a federated learning manager 835 as described with reference to FIG. 8.

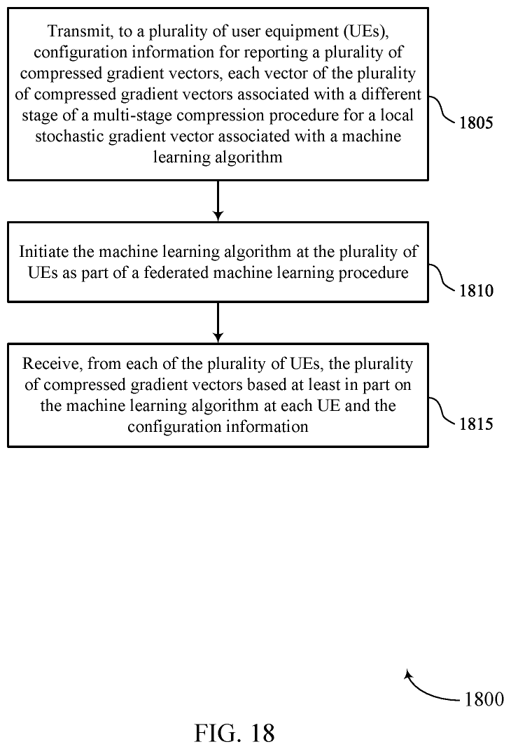

FIG. 18 shows a flowchart illustrating a method 1800 that supports signaling of gradient vectors for federated learning in a wireless communications system in accordance with aspects of the present disclosure. The operations of the method 1800 may be implemented by a base station or its components as described herein. For example, the operations of the method 1800 may be performed by a base station 105 as described with reference to FIGS. 1 through 5 and 10 through 13. In some examples, a base station may execute a set of instructions to control the functional elements of the base station to perform the described functions. Additionally or alternatively, the base station may perform aspects of the described functions using special-purpose hardware.

At 1805, the method may include transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 1805 may be performed in accordance with examples as disclosed herein. In some examples, aspects of the operations of 1805 may be performed by a configuration manager 1225 as described with reference to FIG. 12.

At 1810, the method may include initiating the machine learning algorithm at the set of multiple UEs as part of a federated machine learning procedure. The operations of 1810 may be performed in accordance with examples as disclosed herein. In some examples, aspects of the operations of 1810 may be performed by a federated learning manager 1230 as described with reference to FIG. 12.

At 1815, the method may include receiving, from each of the set of multiple UEs, the set of multiple compressed gradient vectors based on the machine learning algorithm at each UE and the configuration information. The operations of 1815 may be performed in accordance with examples as disclosed herein. In some examples, aspects of the operations of 1815 may be performed by a vector quantization manager 1235 as described with reference to FIG. 12.

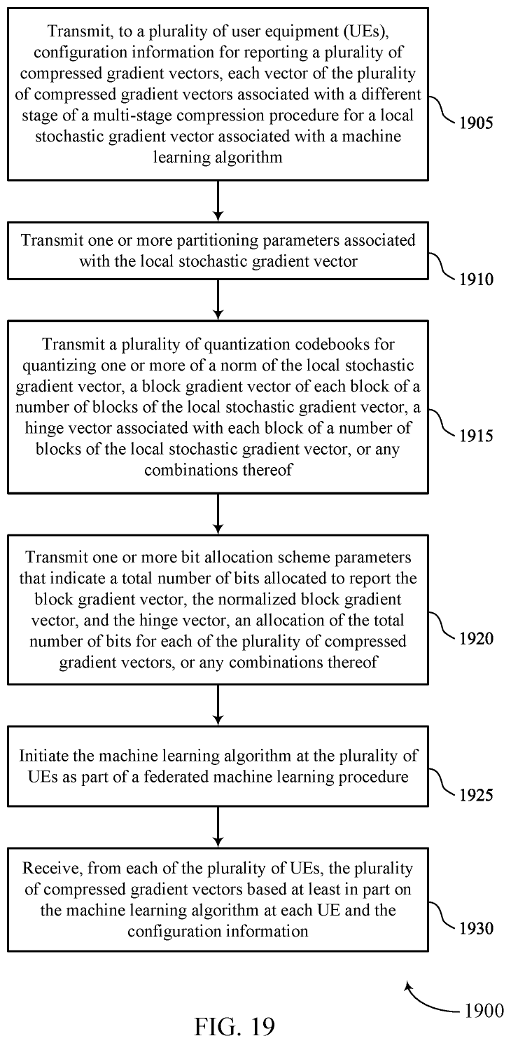

FIG. 19 shows a flowchart illustrating a method 1900 that supports signaling of gradient vectors for federated learning in a wireless communications system in accordance with aspects of the present disclosure. The operations of the method 1900 may be implemented by a base station or its components as described herein. For example, the operations of the method 1900 may be performed by a base station 105 as described with reference to FIGS. 1 through 5 and 10 through 13. In some examples, a base station may execute a set of instructions to control the functional elements of the base station to perform the described functions. Additionally or alternatively, the base station may perform aspects of the described functions using special-purpose hardware.

At 1905, the method may include transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 1905 may be performed in accordance with examples as disclosed herein. In some examples, aspects of the operations of 1905 may be performed by a configuration manager 1225 as described with reference to FIG. 12.

At 1910, the method may include transmitting one or more partitioning parameters associated with the local stochastic gradient vector. The operations of 1910 may be performed in accordance with examples as disclosed herein. In some examples, aspects of the operations of 1910 may be performed by a partitioning manager 1240 as described with reference to FIG. 12.

At 1915, the method may include transmitting a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof. The operations of 1915 may be performed in accordance with examples as disclosed herein. In some examples, aspects of the operations of 1915 may be performed by a quantization codebook manager 1245 as described with reference to FIG. 12.

At 1920, the method may include transmitting one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof. The operations of 1920 may be performed in accordance with examples as disclosed herein. In some examples, aspects of the operations of 1920 may be performed by a configuration manager 1225 as described with reference to FIG. 12.

At 1925, the method may include initiating the machine learning algorithm at the set of multiple UEs as part of a federated machine learning procedure. The operations of 1925 may be performed in accordance with examples as disclosed herein. In some examples, aspects of the operations of 1925 may be performed by a federated learning manager 1230 as described with reference to FIG. 12.

At 1930, the method may include receiving, from each of the set of multiple UEs, the set of multiple compressed gradient vectors based on the machine learning algorithm at each UE and the configuration information. The operations of 1930 may be performed in accordance with examples as disclosed herein. In some examples, aspects of the operations of 1930 may be performed by a vector quantization manager 1235 as described with reference to FIG. 12.

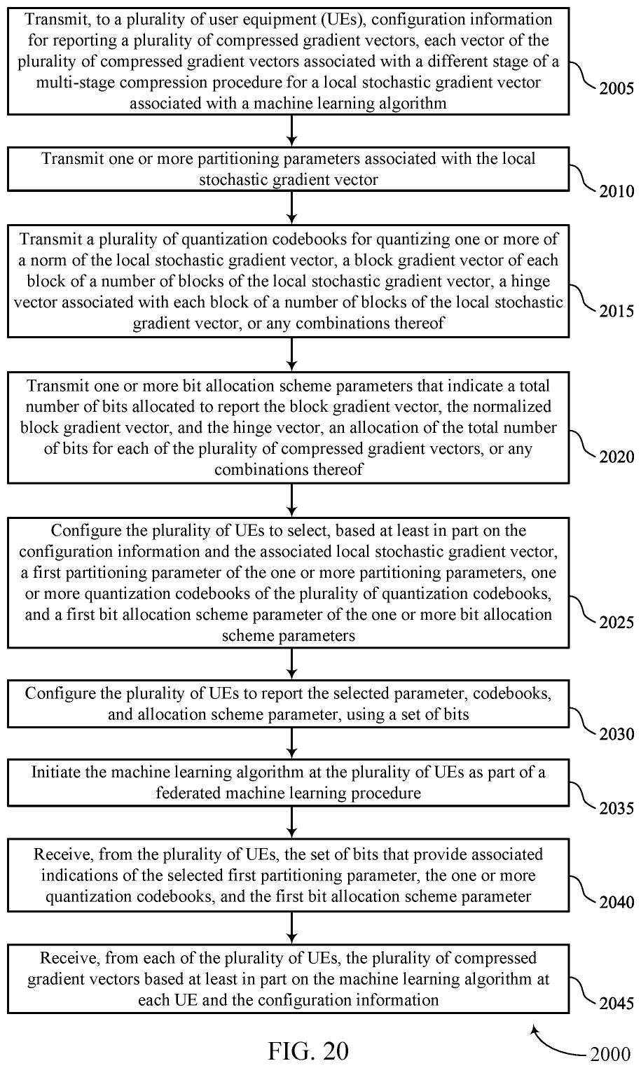

FIG. 20 shows a flowchart illustrating a method 2000 that supports signaling of gradient vectors for federated learning in a wireless communications system in accordance with aspects of the present disclosure. The operations of the method 2000 may be implemented by a base station or its components as described herein. For example, the operations of the method 2000 may be performed by a base station 105 as described with reference to FIGS. 1 through 5 and 10 through 13. In some examples, a base station may execute a set of instructions to control the functional elements of the base station to perform the described functions. Additionally or alternatively, the base station may perform aspects of the described functions using special-purpose hardware.

At 2005, the method may include transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 2005 may be performed in accordance with examples as disclosed herein. In some examples, aspects of the operations of 2005 may be performed by a configuration manager 1225 as described with reference to FIG. 12.

At 2010, the method may include transmitting one or more partitioning parameters associated with the local stochastic gradient vector. The operations of 2010 may be performed in accordance with examples as disclosed herein. In some examples, aspects of the operations of 2010 may be performed by a partitioning manager 1240 as described with reference to FIG. 12.

At 2015, the method may include transmitting a set of multiple quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof. The operations of 2015 may be performed in accordance with examples as disclosed herein. In some examples, aspects of the operations of 2015 may be performed by a quantization codebook manager 1245 as described with reference to FIG. 12.

At 2020, the method may include transmitting one or more bit allocation scheme parameters that indicate a total number of bits allocated to report the block gradient vector, the normalized block gradient vector, and the hinge vector, an allocation of the total number of bits for each of the set of multiple compressed gradient vectors, or any combinations thereof. The operations of 2020 may be performed in accordance with examples as disclosed herein. In some examples, aspects of the operations of 2020 may be performed by a configuration manager 1225 as described with reference to FIG. 12.

At 2025, the method may include configuring the set of multiple UEs to select, based on the configuration information and the associated local stochastic gradient vector, a first partitioning parameter of the one or more partitioning parameters, one or more quantization codebooks of the set of multiple quantization codebooks, and a first bit allocation scheme parameter of the one or more bit allocation scheme parameters. The operations of 2025 may be performed in accordance with examples as disclosed herein. In some examples, aspects of the operations of 2025 may be performed by a configuration manager 1225 as described with reference to FIG. 12.

At 2030, the method may include configuring the set of multiple UEs to report the selected parameter, codebooks, and allocation scheme parameter, using a set of bits. The operations of 2030 may be performed in accordance with examples as disclosed herein. In some examples, aspects of the operations of 2030 may be performed by a configuration manager 1225 as described with reference to FIG. 12.

At 2035, the method may include initiating the machine learning algorithm at the set of multiple UEs as part of a federated machine learning procedure. The operations of 2035 may be performed in accordance with examples as disclosed herein. In some examples, aspects of the operations of 2035 may be performed by a federated learning manager 1230 as described with reference to FIG. 12.

At 2040, the method may include receiving, from the set of multiple UEs, the set of bits that provide associated indications of the selected first partitioning parameter, the one or more quantization codebooks, and the first bit allocation scheme parameter. The operations of 2040 may be performed in accordance with examples as disclosed herein. In some examples, aspects of the operations of 2040 may be performed by a federated learning manager 1230 as described with reference to FIG. 12.

At 2045, the method may include receiving, from each of the set of multiple UEs, the set of multiple compressed gradient vectors based on the machine learning algorithm at each UE and the configuration information. The operations of 2045 may be performed in accordance with examples as disclosed herein. In some examples, aspects of the operations of 2045 may be performed by a vector quantization manager 1235 as described with reference to FIG. 12.

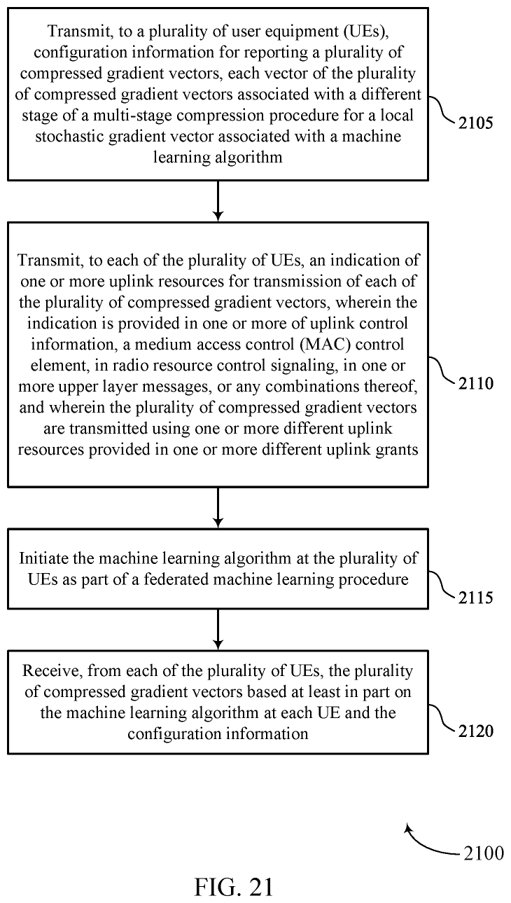

FIG. 21 shows a flowchart illustrating a method 2100 that supports signaling of gradient vectors for federated learning in a wireless communications system in accordance with aspects of the present disclosure. The operations of the method 2100 may be implemented by a base station or its components as described herein. For example, the operations of the method 2100 may be performed by a base station 105 as described with reference to FIGS. 1 through 5 and 10 through 13. In some examples, a base station may execute a set of instructions to control the functional elements of the base station to perform the described functions. Additionally or alternatively, the base station may perform aspects of the described functions using special-purpose hardware.

At 2105, the method may include transmitting, to a set of multiple user equipment (UEs), configuration information for reporting a set of multiple compressed gradient vectors, each vector of the set of multiple compressed gradient vectors associated with a different stage of a multi-stage compression procedure for a local stochastic gradient vector associated with a machine learning algorithm. The operations of 2105 may be performed in accordance with examples as disclosed herein. In some examples, aspects of the operations of 2105 may be performed by a configuration manager 1225 as described with reference to FIG. 12.

At 2110, the method may include transmitting, to each of the set of multiple UEs, an indication of one or more uplink resources for transmission of each of the set of multiple compressed gradient vectors, where the indication is provided in one or more of uplink control information, a medium access control (MAC) control element, in radio resource control signaling, in one or more upper layer messages, or any combinations thereof, and where the set of multiple compressed gradient vectors are transmitted using one or more different uplink resources provided in one or more different uplink grants. The operations of 2110 may be performed in accordance with examples as disclosed herein. In some examples, aspects of the operations of 2110 may be performed by a federated learning manager 1230 as described with reference to FIG. 12.

At 2115, the method may include initiating the machine learning algorithm at the set of multiple UEs as part of a federated machine learning procedure. The operations of 2115 may be performed in accordance with examples as disclosed herein. In some examples, aspects of the operations of 2115 may be performed by a federated learning manager 1230 as described with reference to FIG. 12.

At 2120, the method may include receiving, from each of the set of multiple UEs, the set of multiple compressed gradient vectors based on the machine learning algorithm at each UE and the configuration information. The operations of 2120 may be performed in accordance with examples as disclosed herein. In some examples, aspects of the operations of 2120 may be performed by a vector quantization manager 1235 as described with reference to FIG. 12.

The following provides an overview of aspects of the present disclosure:

Aspect 1: A method for wireless communication at a UE, comprising: receiving, from a base station, configuration information for reporting a plurality of compressed gradient vectors, each vector of the plurality of compressed gradient vectors associated with a different stage of a multi-stage compression procedure for a local stochastic gradient vector associated with a machine learning algorithm; identifying each compressed gradient vector of the plurality of compressed gradient vectors based at least in part on the machine learning algorithm at the UE and the configuration information; transmitting each compressed gradient vector of the plurality of compressed gradient vectors to the base station based at least in part on the configuration information.

Aspect 2: The method of aspect 1, wherein the receiving the configuration information further comprises: receiving one or more partitioning parameters associated with the local stochastic gradient vector; receiving a plurality of quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof; and receiving one or more bit allocation scheme parameters that indicate a total number of bits allocated to report the block gradient vector, the normalized block gradient vector, and the hinge vector, an allocation of the total number of bits for each of the plurality of compressed gradient vectors, or any combinations thereof.

Aspect 3: The method of aspect 2, wherein the one or more partitioning parameters indicate a number of blocks of a stochastic gradient that are to be included in the local stochastic gradient vector, a vector length of each block of the number of blocks, or any combinations thereof; and the plurality of quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

Aspect 4: The method of any of aspects 2 through 3, wherein the receiving the configuration information further comprises: receiving one or more configuration parameters in radio resource control signaling, in a medium access control (MAC) control element, in downlink control information, in one or more higher layer or application layer communications, or any combinations thereof.

Aspect 5: The method of any of aspects 2 through 4, further comprising: selecting, based at least in part on the configuration information and the local stochastic gradient vector, a first partitioning parameter of the one or more partitioning parameters, one or more quantization codebooks of the plurality of quantization codebooks, and a first bit allocation scheme parameter of the one or more bit allocation scheme parameters; and transmitting, to the base station, an indication of the selected first partitioning parameter, the one or more quantization codebooks, and the first bit allocation scheme parameter using a set of bits that is configured by the configuration information.

Aspect 6: The method of aspect 5, wherein the set of bits is explicitly indicated by the base station or identified based at least in part on an uplink resource for reporting the plurality of compressed gradient vectors, and wherein an order of bits within a payload that provides the plurality of compressed gradient vectors is indicated in the configuration information or is predefined at the UE.

Aspect 7: The method of any of aspects 1 through 6, wherein the machine learning algorithm provides a plurality of rounds of compressed gradient vector reporting, and wherein the configuration information is provided separately for each of the plurality or rounds, or the configuration information is applied to each of the plurality of rounds.

Aspect 8: The method of any of aspects 1 through 7, wherein the plurality of compressed gradient vectors is determined based at least in part on a partitioning parameter for the local stochastic gradient vector, one or more quantization codebooks associated with each of the plurality of compressed gradient vectors, and a payload format for reporting the plurality of compressed gradient vectors, and wherein the partitioning parameter, the one or more quantization codebooks, and the payload format are provided with the configuration information, are selected from a set of available parameters, codebooks, and payload formats that are provided by the base station, or are determined entirely or partly by the UE.

Aspect 9: The method of aspect 1, wherein the configuration information further indicates a format for a block-quantized gradient report that includes a plurality of parts for reporting the plurality of compressed gradient vectors, and a quantity of bits in each of the plurality of parts.

Aspect 10: The method of aspect 9, wherein at least one of the plurality of parts has a different quantity of bits than one or more other of the plurality of parts, and wherein the quantity of bits of each of the plurality of parts is provided by the configuration information or is predefined at the UE.

Aspect 11: The method of any of aspects 9 through 10, wherein the block-quantized gradient report includes a first part that indicates a quantized value of a norm of the local stochastic gradient vector that is based on a first bit allocation for an associated scalar quantizer, a second part that indicates quantized values of a plurality of normalized block gradients of the local stochastic gradient vector that are based on a second bit allocation for a uniform and even Grassmannian quantizer, and a third part that indicates quantized values of a hinge vector associated with the plurality of normalized block gradients that are based on a third bit allocation for a positive Grassmannian quantizer.

Aspect 12: The method of aspect 1, further comprising: receiving, from the base station, an indication of one or more uplink resources for transmission of each of the plurality of compressed gradient vectors, wherein the indication is provided in one or more of uplink control information, a medium access control (MAC) control element, in radio resource control signaling, in one or more upper layer messages, or any combinations thereof, and wherein the plurality of compressed gradient vectors are transmitted using one or more different uplink resources provided in one or more different uplink grants.

Aspect 13: The method of aspect 12, wherein the one or more different uplink grants include a plurality of configured uplink grants for uplink shared channel transmissions, and wherein different compressed gradient vectors of the plurality of compressed gradient vectors are transmitted using different configured uplink grants of the plurality of configured uplink grants, and wherein the plurality of configured uplink grants are each associated with different compressed gradient vectors based at least in part on an indication provided in the configuration information, a predefined association at the UE, or based on a determination made at the UE and reported to the base station.

Aspect 14: A method for wireless communication at a base station, comprising: transmitting, to a plurality of user equipment (UEs), configuration information for reporting a plurality of compressed gradient vectors, each vector of the plurality of compressed gradient vectors associated with a different stage of a multi-stage compression procedure for a local stochastic gradient vector associated with a machine learning algorithm; initiating the machine learning algorithm at the plurality of UEs as part of a federated machine learning procedure; and receiving, from each of the plurality of UEs, the plurality of compressed gradient vectors based at least in part on the machine learning algorithm at each UE and the configuration information.

Aspect 15: The method of aspect 14, wherein the transmitting the configuration information further comprises: transmitting one or more partitioning parameters associated with the local stochastic gradient vector; transmitting a plurality of quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof; and transmitting one or more bit allocation scheme parameters that indicate a total number of bits allocated to report the block gradient vector, the normalized block gradient vector, and the hinge vector, an allocation of the total number of bits for each of the plurality of compressed gradient vectors, or any combinations thereof.

Aspect 16: The method of aspect 15, wherein the one or more partitioning parameters indicate a number of blocks of a stochastic gradient that are to be included in the local stochastic gradient vector, a vector length of each block of the number of blocks, or any combinations thereof; and the plurality of quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

Aspect 17: The method of any of aspects 15 through 16, further comprising: configuring the plurality of UEs to select, based at least in part on the configuration information and the associated local stochastic gradient vector, a first partitioning parameter of the one or more partitioning parameters, one or more quantization codebooks of the plurality of quantization codebooks, and a first bit allocation scheme parameter of the one or more bit allocation scheme parameters; configuring the plurality of UEs to report the selected parameter, codebooks, and allocation scheme parameter, using a set of bits; and receiving, from the plurality of UEs, the set of bits that provide associated indications of the selected first partitioning parameter, the one or more quantization codebooks, and the first bit allocation scheme parameter.

Aspect 18: The method of aspect 14, wherein the plurality of compressed gradient vectors are determined based at least in part on a partitioning parameter for the local stochastic gradient vector, one or more quantization codebooks associated with each of the plurality of compressed gradient vectors, and a payload format for reporting the plurality of compressed gradient vectors, and wherein the partitioning parameter, the one or more quantization codebooks, and the payload format are provided with the configuration information, are selected from a set of available parameters, codebooks, and payload formats that are provided by the base station, or are determined entirely or partly by the UE.

Aspect 19: The method of any of aspects 14 through 18, wherein the configuration information further indicates a format for a block-quantized gradient report that includes a plurality of parts for reporting the plurality of compressed gradient vectors, and a quantity of bits in each of the plurality of parts.

Aspect 20: The method of aspect 19, wherein at least one of the plurality of parts has a different quantity of bits than one or more other of the plurality of parts, and wherein the quantity of bits of each of the plurality of parts is provided by the configuration information or is predefined at the UE.

Aspect 21: The method of any of aspects 19 through 20, wherein the block-quantized gradient report includes a first part that indicates a quantized value of a norm of the local stochastic gradient vector that is based on a first bit allocation for an associated scalar quantizer, a second part that indicates quantized values of a plurality of normalized block gradients of the local stochastic gradient vector that are based on a second bit allocation for a uniform and even Grassmannian quantizer, and a third part that indicates quantized values of a hinge vector associated with the plurality of normalized block gradients that are based on a third bit allocation for a positive Grassmannian quantizer.

Aspect 22: The method of aspect 14, further comprising: transmitting, to each of the plurality of UEs, an indication of one or more uplink resources for transmission of each of the plurality of compressed gradient vectors, wherein the indication is provided in one or more of uplink control information, a medium access control (MAC) control element, in radio resource control signaling, in one or more upper layer messages, or any combinations thereof, and wherein the plurality of compressed gradient vectors are transmitted using one or more different uplink resources provided in one or more different uplink grants.

Aspect 23: The method of aspect 22, wherein the one or more different uplink grants include a plurality of configured uplink grants for uplink shared channel transmissions, and wherein different compressed gradient vectors of the plurality of compressed gradient vectors are transmitted using different configured uplink grants of the plurality of configured uplink grants, and wherein the plurality of configured uplink grants are each associated with different compressed gradient vectors based at least in part on an indication provided in the configuration information, a predefined association at the UE, or based on a determination made at the UE and reported to the base station.

Aspect 24: An apparatus for wireless communication at a UE, comprising a processor; memory coupled with the processor; and instructions stored in the memory and executable by the processor to cause the apparatus to perform a method of any of aspects 1 through 13.

Aspect 25: An apparatus for wireless communication at a UE, comprising at least one means for performing a method of any of aspects 1 through 13.

Aspect 26: A non-transitory computer-readable medium storing code for wireless communication at a UE, the code comprising instructions executable by a processor to perform a method of any of aspects 1 through 13.

Aspect 27: An apparatus for wireless communication at a base station, comprising a processor; memory coupled with the processor; and instructions stored in the memory and executable by the processor to cause the apparatus to perform a method of any of aspects 14 through 23.

Aspect 28: An apparatus for wireless communication at a base station, comprising at least one means for performing a method of any of aspects 14 through 23.

Aspect 29: A non-transitory computer-readable medium storing code for wireless communication at a base station, the code comprising instructions executable by a processor to perform a method of any of aspects 14 through 23.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for wireless communication at a user equipment (UE), comprising:
receiving, from a base station, configuration information for reporting a plurality of compressed gradient vectors, each vector of the plurality of compressed gradient vectors associated with a different stage of a multi-stage compression procedure for a local stochastic gradient vector associated with a machine learning algorithm;
identifying each compressed gradient vector of the plurality of compressed gradient vectors based at least in part on the machine learning algorithm at the UE and the configuration information;
transmitting each compressed gradient vector of the plurality of compressed gradient vectors to the base station based at least in part on the configuration information.

2. The method of claim 1, wherein the receiving the configuration information further comprises:
receiving one or more partitioning parameters associated with the local stochastic gradient vector;
receiving a plurality of quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof; and
receiving one or more bit allocation scheme parameters that indicate a total number of bits allocated to report the block gradient vector, the normalized block gradient vector, and the hinge vector, an allocation of the total number of bits for each of the plurality of compressed gradient vectors, or any combinations thereof.

3. The method of claim 2, wherein:
the one or more partitioning parameters indicate a number of blocks of a stochastic gradient that are to be included in the local stochastic gradient vector, a vector length of each block of the number of blocks, or any combinations thereof; and
the plurality of quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof

4. The method of claim 2, wherein the receiving the configuration information further comprises:
receiving one or more configuration parameters in radio resource control signaling, in a medium access control (MAC) control element, in downlink control information, in one or more higher layer or application layer communications, or any combinations thereof.

5. The method of claim 2, further comprising:
selecting, based at least in part on the configuration information and the local stochastic gradient vector, a first partitioning parameter of the one or more partitioning parameters, one or more quantization codebooks of the plurality of quantization codebooks, and a first bit allocation scheme parameter of the one or more bit allocation scheme parameters; and
transmitting, to the base station, an indication of the selected first partitioning parameter, the one or more quantization codebooks, and the first bit allocation scheme parameter using a set of bits that is configured by the configuration information.

6. The method of claim 5, wherein the set of bits is explicitly indicated by the base station or identified based at least in part on an uplink resource for reporting the plurality of compressed gradient vectors, and wherein an order of bits within a payload that provides the plurality of compressed gradient vectors is indicated in the configuration information or is predefined at the UE.

7. The method of claim 1, wherein the machine learning algorithm provides a plurality of rounds of compressed gradient vector reporting, and wherein the configuration information is provided separately for each of the plurality or rounds, or the configuration information is applied to each of the plurality of rounds.

8. The method of claim 1, wherein:
the plurality of compressed gradient vectors is determined based at least in part on a partitioning parameter for the local stochastic gradient vector, one or more quantization codebooks associated with each of the plurality of compressed gradient vectors, and a payload format for reporting the plurality of compressed gradient vectors, and
wherein the partitioning parameter, the one or more quantization codebooks, and the payload format are provided with the configuration information, are selected from a set of available parameters, codebooks, and payload formats that are provided by the base station, or are determined entirely or partly by the UE.

9. The method of claim 1, wherein the configuration information further indicates a format for a block-quantized gradient report that includes a plurality of parts for reporting the plurality of compressed gradient vectors, and a quantity of bits in each of the plurality of parts.

10. The method of claim 9, wherein at least one of the plurality of parts has a different quantity of bits than one or more other of the plurality of parts, and wherein quantity of bits of each of the plurality of parts is provided by the configuration information or is predefined at the UE.

11. The method of claim 9, wherein the block-quantized gradient report includes a first part that indicates a quantized value of a norm of the local stochastic gradient vector that is based on a first bit allocation for an associated scalar quantizer, a second part that indicates quantized values of a plurality of normalized block gradients of the local stochastic gradient vector that are based on a second bit allocation for a uniform and even Grassmannian quantizer, and a third part that indicates quantized values of a hinge vector associated with the plurality of normalized block gradients that are based on a third bit allocation for a positive Grassmannian quantizer.

12. The method of claim 1, further comprising:
receiving, from the base station, an indication of one or more uplink resources for transmission of each of the plurality of compressed gradient vectors, wherein the indication is provided in one or more of uplink control information, a medium access control (MAC) control element, in radio resource control signaling, in one or more upper layer messages, or any combinations thereof, and wherein the plurality of compressed gradient vectors are transmitted using one or more different uplink resources provided in one or more different uplink grants.

13. The method of claim 12, wherein:
the one or more different uplink grants include a plurality of configured uplink grants for uplink shared channel transmissions, and wherein different compressed gradient vectors of the plurality of compressed gradient vectors are transmitted using different configured uplink grants of the plurality of configured uplink grants, and wherein the plurality of configured uplink grants are each associated with different compressed gradient vectors based at least in part on an indication provided in the configuration information, a predefined association at the UE, or based on a determination made at the UE and reported to the base station.

14. A method for wireless communication at a base station, comprising:
transmitting, to a plurality of user equipment (UEs), configuration information for reporting a plurality of compressed gradient vectors, each vector of the plurality of compressed gradient vectors associated with a different stage of a multi-stage compression procedure for a local stochastic gradient vector associated with a machine learning algorithm;
initiating the machine learning algorithm at the plurality of UEs as part of a federated machine learning procedure; and
receiving, from each of the plurality of UEs, the plurality of compressed gradient vectors based at least in part on the machine learning algorithm at each UE and the configuration information.

15. The method of claim 14, wherein the transmitting the configuration information further comprises:
transmitting one or more partitioning parameters associated with the local stochastic gradient vector;
transmitting a plurality of quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof; and
transmitting one or more bit allocation scheme parameters that indicate a total number of bits allocated to report the block gradient vector, the normalized block gradient vector, and the hinge vector, an allocation of the total number of bits for each of the plurality of compressed gradient vectors, or any combinations thereof.

16. The method of claim 15, wherein:
the one or more partitioning parameters indicate a number of blocks of a stochastic gradient that are to be included in the local stochastic gradient vector, a vector length of each block of the number of blocks, or any combinations thereof; and
the plurality of quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof

17. The method of claim 15, further comprising:
configuring the plurality of UEs to select, based at least in part on the configuration information and the associated local stochastic gradient vector, a first partitioning parameter of the one or more partitioning parameters, one or more quantization codebooks of the plurality of quantization codebooks, and a first bit allocation scheme parameter of the one or more bit allocation scheme parameters;
configuring the plurality of UEs to report the selected parameter, codebooks, and allocation scheme parameter, using a set of bits; and
receiving, from the plurality of UEs, the set of bits that provide associated indications of the selected first partitioning parameter, the one or more quantization codebooks, and the first bit allocation scheme parameter.

18. The method of claim 14, wherein:
the plurality of compressed gradient vectors are determined based at least in part on a partitioning parameter for the local stochastic gradient vector, one or more quantization codebooks associated with each of the plurality of compressed gradient vectors, and a payload format for reporting the plurality of compressed gradient vectors, and
wherein the partitioning parameter, the one or more quantization codebooks, and the payload format are provided with the configuration information, are selected from a set of available parameters, codebooks, and payload formats that are provided by the base station, or are determined entirely or partly by the UE.

19. The method of claim 14, wherein the configuration information further indicates a format for a block-quantized gradient report that includes a plurality of parts for reporting the plurality of compressed gradient vectors, and a quantity of bits in each of the plurality of parts.

20. The method of claim 19, wherein at least one of the plurality of parts has a different quantity of bits than one or more other of the plurality of parts, and wherein the quantity of bits of each of the plurality of parts is provided by the configuration information or is predefined at the UE.

21. The method of claim 19, wherein the block-quantized gradient report includes a first part that indicates a quantized value of a norm of the local stochastic gradient vector that is based on a first bit allocation for an associated scalar quantizer, a second part that indicates quantized values of a plurality of normalized block gradients of the local stochastic gradient vector that are based on a second bit allocation for a uniform and even Grassmannian quantizer, and a third part that indicates quantized values of a hinge vector associated with the plurality of normalized block gradients that are based on a third bit allocation for a positive Grassmannian quantizer.

22. The method of claim 14, further comprising:
transmitting, to each of the plurality of UEs, an indication of one or more uplink resources for transmission of each of the plurality of compressed gradient vectors, wherein the indication is provided in one or more of uplink control information, a medium access control (MAC) control element, in radio resource control signaling, in one or more upper layer messages, or any combinations thereof, and wherein the plurality of compressed gradient vectors are transmitted using one or more different uplink resources provided in one or more different uplink grants.

23. The method of claim 22, wherein:
the one or more different uplink grants include a plurality of configured uplink grants for uplink shared channel transmissions, and wherein different compressed gradient vectors of the plurality of compressed gradient vectors are transmitted using different configured uplink grants of the plurality of configured uplink grants, and wherein
the plurality of configured uplink grants are each associated with different compressed gradient vectors based at least in part on an indication provided in the configuration information, a predefined association at the UE, or based on a determination made at the UE and reported to the base station.

24. An apparatus for wireless communication at a user equipment (UE), comprising:
means for receiving, from a base station, configuration information for reporting a plurality of compressed gradient vectors, each vector of the plurality of compressed gradient vectors associated with a different stage of a multi-stage compression procedure for a local stochastic gradient vector associated with a machine learning algorithm;
means for identifying each compressed gradient vector of the plurality of compressed gradient vectors based at least in part on the machine learning algorithm at the UE and the configuration information;
means for transmitting each compressed gradient vector of the plurality of compressed gradient vectors to the base station based at least in part on the configuration information.

25. The apparatus of claim 24, wherein the means for receiving:
receives one or more partitioning parameters associated with the local stochastic gradient vector;
receives a plurality of quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof; and
receives one or more bit allocation scheme parameters that indicate a total number of bits allocated to report the block gradient vector, the normalized block gradient vector, and the hinge vector, an allocation of the total number of bits for each of the plurality of compressed gradient vectors, or any combinations thereof.

26. The apparatus of claim 25, wherein:
the one or more partitioning parameters indicate a number of blocks of a stochastic gradient that are to be included in the local stochastic gradient vector, a vector length of each block of the number of blocks, or any combinations thereof; and
the plurality of quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

27. An apparatus for wireless communication at a base station, comprising:
means for transmitting, to a plurality of user equipment (UEs), configuration information for reporting a plurality of compressed gradient vectors, each vector of the plurality of compressed gradient vectors associated with a different stage of a multi-stage compression procedure for a local stochastic gradient vector associated with a machine learning algorithm;
means for initiating the machine learning algorithm at the plurality of UEs as part of a federated machine learning procedure; and
means for receiving, from each of the plurality of UEs, the plurality of compressed gradient vectors based at least in part on the machine learning algorithm at each UE and the configuration information.

28. The apparatus of claim 27, wherein the means for transmitting:
transmits one or more partitioning parameters associated with the local stochastic gradient vector;
transmits a plurality of quantization codebooks for quantizing one or more of a norm of the local stochastic gradient vector, a block gradient vector of each block of a number of blocks of the local stochastic gradient vector, a hinge vector associated with each block of a number of blocks of the local stochastic gradient vector, or any combinations thereof; and
transmits one or more bit allocation scheme parameters that indicate a total number of bits allocated to report the block gradient vector, the normalized block gradient vector, and the hinge vector, an allocation of the total number of bits for each of the plurality of compressed gradient vectors, or any combinations thereof.

29. The apparatus of claim 28, wherein:
the one or more partitioning parameters indicate a number of blocks of a stochastic gradient that are to be included in the local stochastic gradient vector, a vector length of each block of the number of blocks, or any combinations thereof; and
the plurality of quantization codebooks include one or more available scalar quantization codebooks for quantizing the norm of the local stochastic gradient vector, one or more available uniform and even Grassmannian quantization codebooks for quantizing each block of the block gradient vector, one or more positive Grassmannian quantization codebooks for quantizing the hinge vector, or any combinations thereof.

30. The apparatus of claim 28, further comprising:
means for configuring the plurality of UEs to select, based at least in part on the configuration information and the associated local stochastic gradient vector, a first partitioning parameter of the one or more partitioning parameters, one or more quantization codebooks of the plurality of quantization codebooks, and a first bit allocation scheme parameter of the one or more bit allocation scheme parameters; and
means for configuring the plurality of UEs to report the selected parameter, codebooks, and allocation scheme parameter, using a set of bits, and
wherein the means for receiving receives, from the plurality of UEs, the set of bits that provide associated indications of the selected first partitioning parameter, the one or more quantization codebooks, and the first bit allocation scheme parameter.
